(19) United States
(12) Patent Application Publication
(10) Pub. No.: US 2026/0324244 A1
(43) Pub. Date: Oct. 15, 2026

(54) DISPLAY MODULE, AND ELECTRONIC APPARATUS INCLUDING THE SAME

(71) Applicant: Samsung Display Co., Ltd., Yongin-si (KR)

(72) Inventors: CHANSU KIM, Yongin-si (KR); INOK KIM, Yongin-si (KR); GAK SEOK LEE, Yongin-si (KR); SANGHUN LEE, Yongin-si (KR); CHANG-SOON JANG, Yongin-si (KR)

(21) Appl. No.: 19/467,555

(22) Filed: Feb. 2, 2026

(30) Foreign Application Priority Data
Apr. 14, 2025 (KR) 10-2025-0048330

(51) Int. Cl. H10K 59/38; H10K 59/131; H10K 102/00

(52) U.S. Cl. CPC H10K 59/38; H10K 59/131; H10K 2102/351

(57) ABSTRACT

Provides is a display module including a display substrate divided into a display region and a non-display region adjacent to the display region, the display substrate including light-emitting elements arranged in the display region, and a light control substrate facing the display substrate and including a color filter layer, a light conversion layer, and a low-refractive layer located between the color filter layer and the light conversion layer, wherein a first thickness of the low-refractive layer overlapping the display region is about 0.3 μm to about 1.0 μm.

### CROSS-REFERENCE TO RELATED APPLICATIONS

The present application claims priority to and the benefit of Korean Patent Application No. 10-2025-0048330, filed on Apr. 14, 2025, the entire contents of which are hereby incorporated by reference.

### BACKGROUND

### 1. Field

Embodiments the present disclosure herein relate to a display module and an electronic apparatus including the same, and for example, to a display module having improved reliability and an electronic apparatus including the same.

### 2. Description of Related Art

Multimedia display devices, such as televisions, mobile phones, tablet PCs, computers, navigation units, and game consoles, include display substrates for displaying images. Such a display substrate may include a plurality of pixels for displaying an image, and each of the pixels may include a light-emitting element for generating light and a driving element connected to the light-emitting element.

In order to improve the light emission efficiency and color purity of display devices, various functional layers may be required in the display devices. However, gas or moisture may enter the display devices via a functional layer that is relatively vulnerable to moisture permeation, and this may cause defects in the display devices.

### SUMMARY

The present disclosure provides an electronic apparatus having improved reliability, wherein a path through which gas and/or moisture flows from an edge of the electronic apparatus into a low-refractive layer is blocked or reduced, thereby preventing or reducing deterioration and failure of the electronic apparatus.

An embodiment of the present disclosure provides a display module including a display substrate divided into a display region and a non-display region adjacent to the display region, the display substrate including light-emitting elements arranged in the display region, and a light control substrate facing the display substrate and including a color filter layer, a light conversion layer, and a low-refractive layer located between the color filter layer and the light conversion layer, wherein a first thickness of the low-refractive layer overlapping the display region is about 0.3 μm to about 1.0 μm.

In an embodiment, the display region may include a light-emitting region and a non-light emitting region surrounding the light-emitting region, the color filter layer may include a first color filter, a second color filter, and a third color filter having different colors, and the first to third color filters overlapping the non-light emitting region may overlap each other.

In an embodiment, the color filter layer may include a first surface facing the display substrate, and the first surface may include a first stepped region overlapping the non-light emitting region.

In an embodiment, an edge of one selected from the first to third color filters overlapping the non-light emitting region may be on a back surface of another one selected from the first to third color filters, thereby forming the first stepped region.

In an embodiment, the non-display region may include a pad region and a non-pad region adjacent to the pad region, and the display substrate may further include a plurality of pads arranged in the pad region.

In an embodiment, a second thickness of the low-refractive layer overlapping the non-pad region may be less than a third thickness of the low-refractive layer overlapping the pad region.

In an embodiment, the color filter layer may include a first color filter, a second color filter, and a third color filter having different colors, and the first to third color filters overlapping the non-display region may overlap each other.

In an embodiment, edges of the first to third color filters overlapping the non-pad region may be aligned with each other.

In an embodiment, the color filter layer may include a first surface facing the display substrate, and the first surface may include a second stepped region overlapping the pad region.

In an embodiment, the second stepped region may include a (2-1)-th stepped region and a (2-2)-th stepped region, an edge of the first color filter overlapping the pad region may be on a back surface of the second color filter overlapping the pad region, thereby providing the (2-1)-th stepped region, and an edge of the second color filter overlapping the pad region may be on a back surface of the third color filter overlapping the pad region, thereby providing the (2-2)-th stepped region.

In an embodiment, the light conversion layer may include a bank portion in which openings respectively overlapping the light-emitting elements are defined and a light conversion portion and a light transmissive portion respectively arranged in the openings, wherein the light conversion portion includes a quantum dot configured to convert a wavelength of source light of the light-emitting element.

In an embodiment, a refractive index of the low-refractive layer may be less than a refractive index of the light conversion portion.

In an embodiment, the light conversion portion may include a first light conversion portion configured to convert the source light into first color light and a second light conversion portion configured to convert the source light into second color light, wherein the first color filter overlaps the first light conversion portion, the second color filter overlaps the second light conversion portion, and the third color filter overlaps the light transmissive portion.

In an embodiment, the low-refractive layer may be derived from a resin composition, and viscosity of the resin composition may be about 1.5 cP to about 2.5 cP.

In an embodiment, a weight percentage of solids relative to a total weight of the resin composition may be about 6% to about 10%.

In an embodiment, the resin composition may include a solvent including a first solvent and a second solvent, the first solvent may include propylene glycol monomethyl ether acetate (PGMEA), the second solvent may include γ-butyrolactone (GBL), and a weight percentage of the first solvent relative to a total weight of the solvent may be about 75% to about 90%, and a weight percentage of the second solvent relative to the total weight of the solvent is about 10% to about 25%.

In an embodiment, the light control substrate further may include a capping layer covering a back surface of the low-refractive layer.

In an embodiment, the display module may further include a sealing member provided between the display substrate and the light control substrate and overlapping the non-display region.

In an embodiment of the present disclosure, a display module includes a display substrate including light-emitting elements, and a light control substrate facing the display substrate and including a color filter layer, a light conversion layer, and a low-refractive layer located between the color filter layer and the light conversion layer, wherein the low-refractive layer is derived from a resin composition having viscosity of about 1.5 cP to about 2.5 cP, and a thickness of the low-refractive layer is about 0.3 μm to about 1.0 μm.

In an embodiment of the present disclosure, an electronic apparatus provides an image and includes a display device and a power module configured to supply power to the display device, wherein the display device includes a display module and a window on the display module, and the display module includes a display substrate divided into a display region and a non-display region adjacent to the display region, the display substrate including light-emitting elements arranged in the display region, and a light control substrate facing the display substrate and including a color filter layer, a light conversion layer, and a low-refractive layer located between the color filter layer and the light conversion layer, wherein a first thickness of the low-refractive layer overlapping the display region is about 0.3 μm to about 1.0 μm.

### BRIEF DESCRIPTION OF THE FIGURES

The accompanying drawings are included to provide a further understanding of the subject matter of the present disclosure, and are incorporated in and constitute a part of this specification. The drawings illustrate embodiments of the present disclosure and, together with the description, serve to explain principles of the present disclosure. In the drawings:

FIG. 1 is a block diagram of an electronic apparatus according to an embodiment;

FIG. 2 shows schematic diagrams of an electronic apparatus according to an embodiment;

FIG. 3 is a perspective view of an electronic apparatus according to an embodiment of the present disclosure;

FIG. 4 is an exploded perspective view of an electronic apparatus according to an embodiment of the present disclosure;

FIG. 5 is a cross-sectional view of a display module according to an embodiment of the present disclosure;

FIG. 6 is a plan view of a display module according to an embodiment of the present disclosure;

FIG. 7 is an enlarged plan view of a display substrate according to an embodiment of the present disclosure;

FIG. 8 is a cross-sectional view of a display substrate according to an embodiment of the present disclosure;

FIG. 9 is a cross-sectional view of a display module according to an embodiment of the present disclosure;

FIG. 10 is a cross-sectional view of a display module according to an embodiment of the present disclosure;

FIGS. 11A and 11B are enlarged cross-sectional views of a display module according to an embodiment of the present disclosure;

FIG. 12 is a cross-sectional view of a display module according to an embodiment of the present disclosure;

FIG. 13 is an enlarged cross-sectional view of a display module according to an embodiment of the present disclosure; and

FIG. 14 is a graph showing evaluation of characteristics of display modules in an embodiment and a comparative example.

### DETAILED DESCRIPTION

Because the subject matter of the present disclosure may have various suitable modifications and be embodied in different forms, example embodiments are illustrated in the drawings and described in more detail in the description. However, this is not intended to limit the present disclosure to the example embodiments, and it should be understood that the present disclosure covers all the modifications, equivalents, and replacements within the idea and technical scope of the present disclosure.

In this specification, it will be understood that if (e.g., when) an element (or a region, a layer, a portion, or the like) is referred to as being “on”, “connected to” or “coupled to” another element, it may be directly on, connected to, or coupled to the other element, or other elements may be therebetween.

Like reference numerals or symbols refer to like elements throughout. In the drawings, the thickness, ratio, and size of the elements are exaggerated for effectively describing the technical contents. As used herein, the term “and/or” includes any and all combinations of one or more of the associated listed elements.

It will be understood that, although the terms “first”, “second”, and/or the like may be used herein to describe various elements, the elements are not to be limited by these terms. These terms are only used to distinguish one element from another element. For instance, a first element could be termed a second element without departing from the scope of the present disclosure. Similarly, a second element could be termed a first element. In this specification, the singular expressions “a”, “an” and “the” are intended to include the plural forms as well, unless the context clearly indicates otherwise.

In embodiments, the terms “below”, “under”, “on the lower side”, “above”, “over”, “on the upper side”, or the like may be used to describe the relationships between the elements illustrated in the drawings. These terms are relative concepts and are described on the basis of the directions indicated in the drawings.

It will be further understood that the terms “comprises, includes, has” and/or “comprising, including, having”, if (e.g., when) used in this specification, specify the presence of stated features, numbers, steps, operations, elements, components or combinations thereof, but do not preclude the possibility of the presence or addition of one or more other features, numbers, steps, operations, elements, components, and/or combinations thereof.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the present disclosure are described with reference to the drawings.

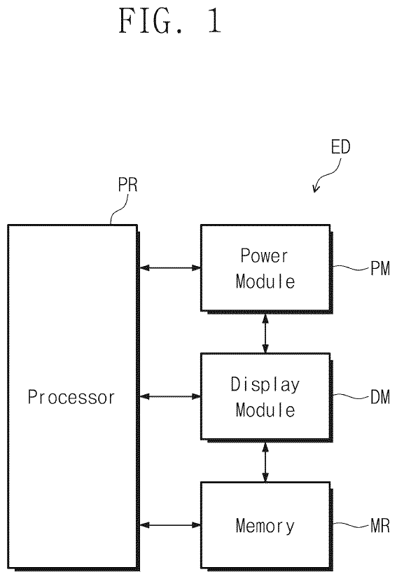

FIG. 1 is a block diagram of an electronic apparatus according to an embodiment. Referring to FIG. 1, an electronic apparatus ED according to an embodiment may include a display module DM, a processor PR, a memory MR, and a power module PM.

The processor PR may include at least one selected from a central processing unit (CPU), an application processor (AP), a graphic processing unit (GPU), a communication processor (CP), an image signal processor (ISP), or a controller.

The memory MR may store data information that is required for the operations of the processor PR and the display module DM. If (e.g., when) the processor PR executes an application stored in the memory MR, image data signals and/or input control signals may be transmitted to the display module DM, and the display module DM may process the received signals and output image information via a display screen. The display module DM may include a display panel for displaying images.

The power module PM may include a power supply module, such as a power adapter and a battery device, and a power conversion module that converts the power supplied by the power supply module and generates power required for the operations of the electronic apparatus ED.

At least one component in the electronic apparatus ED described above may be included in a display module and a display device including the display module according to embodiments described below. In embodiments, some of individual modules functionally included in a single module may be provided inside the display device, while others may be provided separately from the display device. For example, the display device may include the display module DM, and the processor PR, the memory MR, and the power module PM may be provided in the form of other devices inside the electronic apparatus ED which are different from the display device.

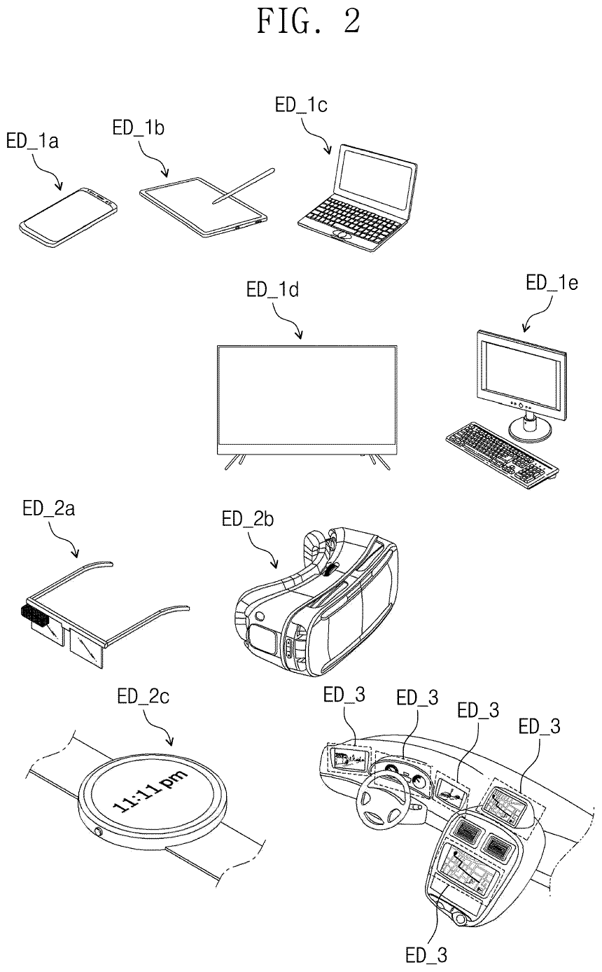

FIG. 2 shows schematic views of embodiments of various suitable electronic apparatuses.

Referring to FIG. 2, various suitable electronic apparatuses including display modules according to embodiments may include image display electronic apparatuses, such as a smartphone ED_1a, a tablet personal computer (PC) ED_1b, a laptop ED_1c, a television (TV) ED_1d, and a desktop monitor ED_1e. In embodiments, the electronic apparatuses may include wearable electronic apparatuses, such as smart glasses ED_2a, a head-mounted display ED_2b, and a smart watch ED_2c. Furthermore, the electronic apparatuses may include a vehicle electronic apparatus ED_3, such as a room mirror display and a center information display (CID) placed on an instrument panel, a center fascia, and/or a dashboard of a vehicle.

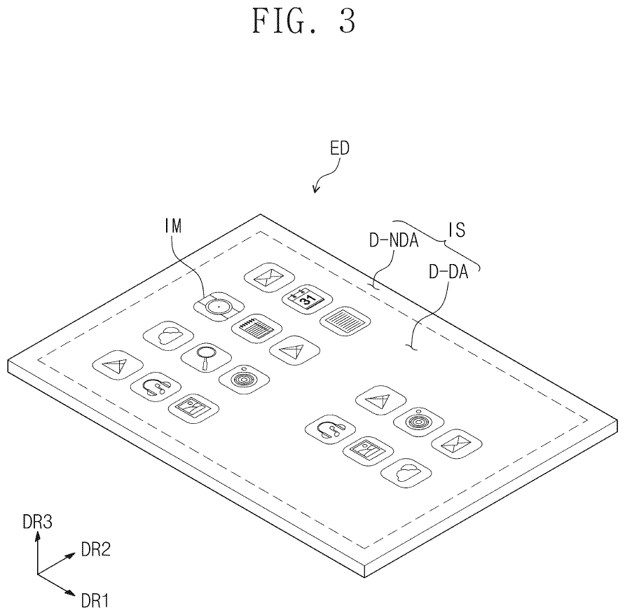

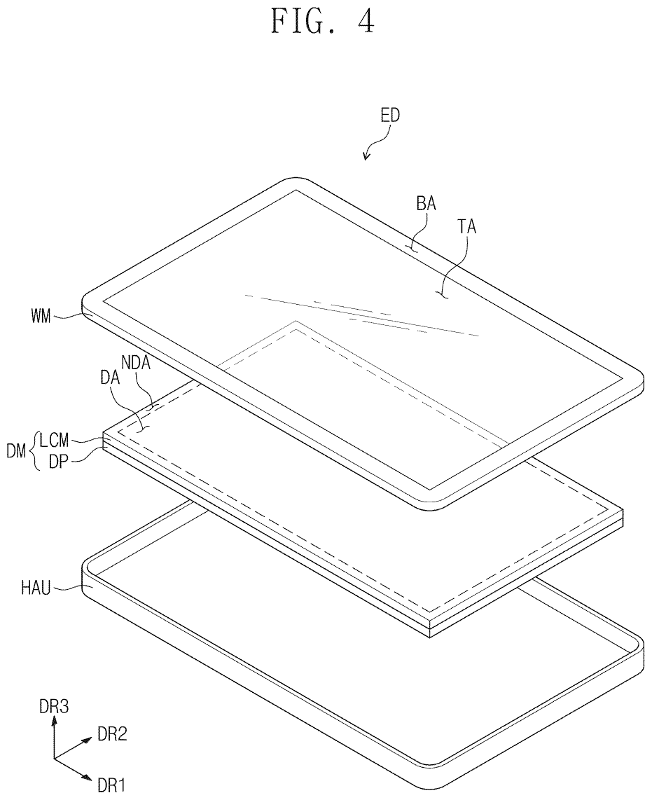

FIG. 3 is a perspective view of an electronic apparatus according to an embodiment of the present disclosure. FIG. 4 is an exploded perspective view of an electronic apparatus according to an embodiment of the present disclosure. FIG. 4 shows a perspective view of the electronic apparatus of FIG. 3. FIGS. 3 and 4 show one example of the image display electronic apparatuses, such as the smartphone ED_1a, the tablet PC ED_1b, the laptop ED_1c, the TV ED_1d, and the desktop monitor ED_1e of FIG. 2, but embodiments of the present disclosure are not limited to those shown in the diagram.

Referring to FIG. 3, the electronic apparatus ED may have a rectangular shape of which the long sides extend in a first direction DR1 and the short sides extend in a second direction DR2 on a plane. However, embodiments of the present disclosure are not limited thereto, and the electronic apparatus ED may have various suitable shapes, such as a circle (e.g., generally a circle) and a polygon.

The electronic apparatus ED may display, in a third direction DR3, an image IM via a display surface IS that is parallel (e.g., substantially parallel) to a plane defined by the first direction DR1 and the second direction DR2. The third direction DR3 may be substantially parallel to the normal direction of the display surface IS. The display surface IS on which the image IM is displayed may correspond to the front surface of the electronic apparatus ED. The image IM may include static images as well as dynamic images. FIG. 3 illustrates application icons as one example of the image IM.

In embodiments, a front surface (or an upper surface) and a rear surface (or a lower surface) of each member or unit may be defined on the basis of the direction in which the image IM is displayed. The front and rear surfaces may be opposed to each other in the third direction DR3, and the normal direction of each of the front and rear surfaces may be parallel (e.g., substantially parallel) to the third direction DR3. The distance between the front surface and the rear surface defined in the third direction DR3 may correspond to the thickness of a member (or a unit).

In the specification, the expression of “in a plan view” may be defined as a state if (e.g., when) viewed in the third direction DR3. In the specification, the expression of “in a cross-section” may be defined as a state if (e.g., when) viewed in the first direction DR1 or the second direction DR2. Also, directions indicated as the first to third directions DR1, DR2, and DR3 may have relative concepts and thus may be changed to other directions.

The display surface IS of the electronic apparatus ED may include a display portion D-DA and a non-display portion D-NDA. The display portion D-DA may be a region inside the front surface of the electronic apparatus ED, on which the image IM is displayed, and a user may view the image IM via the display portion D-DA. The drawing shows an example in which the display portion D-DA has a quadrangular shape in a plan view, but the display portion D-DA may have various suitable shapes according to the design of the electronic apparatus ED.

The non-display portion D-NDA may be a region inside the front surface of the electronic apparatus ED, on which the image IM is not displayed. The non-display portion D-NDA may be a region having a certain color and blocking light. The non-display portion D-NDA may be adjacent to the display portion D-DA. For example, the non-display portion D-NDA may be located outside the display portion D-DA and surround the display portion D-DA. However, this is merely illustrated as an example. The non-display portion D-NDA may be adjacent to only one side of the display portion D-DA or may be located on a side surface of the electronic apparatus ED instead of the front surface thereof. Embodiments of the present disclosure are not limited thereto, and the non-display portion D-NDA may be omitted.

FIG. 3 shows an example in which the display surface IS of the electronic apparatus ED is flat. However, the display surface IS of the electronic apparatus ED is not limited thereto, and embodiments may have a curved shape or a three-dimensional shape.

The electronic apparatus ED may be flexible. Being “flexible” may mean the characteristics of being bendable and encompass all structures from a completely foldable structure to a structure bendable to the order of several nanometers. For example, the electronic apparatus ED that is flexible may be a curved apparatus and/or a foldable apparatus. Embodiments are not limited thereto, and the electronic apparatus ED may be rigid.

The electronic apparatus ED according to an embodiment may sense an external input applied from the outside. External inputs may have various suitable forms, such as pressure, temperature, and light provided from outside. The external inputs may include not only an input that comes into contact with the electronic apparatus ED (e.g., contact by a user's hand and/or a pen), but also an input that is applied in proximity to the electronic apparatus ED (e.g., hovering).

Referring to FIG. 4, the electronic apparatus ED may include a window WM, a display module DM, and an outer case HAU. The display module DM may include a display substrate DP and a light control substrate LCM on the display substrate DP.

The window WM and the outer case HAU may be coupled to each other to define the exterior of the electronic apparatus ED and may provide an inner space capable of accommodating components of the electronic apparatus ED, such as the display panel DM.

The window WM may be on the display module DM. The window WM may protect the display panel DM from external impact. The front surface of the window WM may correspond to the display surface IS (see FIG. 3) of the electronic apparatus ED described above. The front of the window WM may include a transmissive region TA and a bezel region BA.

The transmissive region TA of the window WM may be optically transparent. The image provided by the display module DM may be transmitted via the transmissive region TA of the window WM, and a user may view the image. The transmissive region TA may correspond to the display portion D-DA (see FIG. 3) of the electronic apparatus ED.

The window WM may include an optically transparent insulating material (e.g., optically electrically insulating material). For example, the window WM may include glass, sapphire, plastic (e.g., polymer), and/or the like. The window WM may have a single-layer structure or a multi-layer structure. The window WM may further include functional layers, such as an anti-fingerprint layer, a phase control layer, and a hard coating layer, which are on an optically transparent substrate.

The bezel region BA of the window WM may be provided by depositing, coating, and/or printing a material having a certain color on a transparent substrate. The bezel region BA of the window WM may prevent components of the display module DM, which overlap the bezel region BA, from being visible from the outside (or reduce visibility thereof). The bezel region BA may correspond to the non-display portion D-NDA (see FIG. 3) of the electronic apparatus ED.

The display module DM may be located between the window WM and the outer case HAU. The display module DM may display an image in response to an electrical signal. The display module DM may include a display region DA and a non-display region NDA adjacent to the display region DA.

The display region DA may be a region that is activated in response to an electrical signal. The display region DA may be a region through which an image provided by the display substrate DP is emitted. The display region DA of the display module DM may at least partially overlap the transmissive region TA. The image generated in the display region DA may be visible from the outside via the transmissive region TA.

The non-display region NDA may be adjacent to the display region DA. For example, the non-display region NDA may surround the display region DA. However, embodiments are not limited thereto, and the non-display region NDA may be defined as various suitable shapes. The non-display region NDA may be a region in which a drive circuit and/or a drive wire for driving elements in the display region DA, various suitable signal lines for supplying electrical signals to the elements, and pads are arranged. The non-display region NDA may overlap at least partially the bezel region BA, and the bezel region BA may prevent components of the display module DM, which are arranged in the non-display region NDA, from being visible from the outside (or reduce visibility thereof).

The display substrate DP may be provided in the form of a panel and thus referred to as a display panel. The display substrate DP according to an embodiment may be a light-emitting display panel, and embodiments are not particularly limited thereto. For example, the display substrate DP may include an organic light-emitting display panel, an inorganic light-emitting display panel, and/or a quantum dot light-emitting display panel. A light-emitting layer of the organic light-emitting display panel may include an organic light-emitting material, and a light-emitting layer of the inorganic light-emitting display panel may include an inorganic light-emitting material. A light-emitting layer of the quantum dot light-emitting display panel may include quantum dots and/or quantum rods. Hereinafter, the display substrate DP is described as the organic light-emitting display panel.

The light control substrate LCM may be on the display substrate DP. The light control substrate LCM may be provided on the display substrate DP and then bonded to the display substrate DP by a bonding process. In this specification, the display substrate DP formed at the bottom of the display module DM may be defined as a first substrate, and the light control substrate LCM bonded onto the first substrate may be defined as a second substrate.

The light control substrate LCM may selectively convert or transmit the wavelength of light that is provided by the display substrate DP. Also, the light control substrate LCM may prevent or reduce reflection of external light that is incident from the outside of the electronic apparatus ED.

The outer case HAU may be below the display module DM and accommodate the display module DM. The outer case HAU may include relatively high-rigidity materials. The outer case HAU may protect the display module DM by absorbing impact applied to the display module DM from the outside and preventing or reducing entrance of foreign substances/moisture into the display module DM. The outer case HAU according to an embodiment may be provided as a structure in which a plurality of storage members are coupled to each other.

Also, the electronic apparatus ED may further include an input sensing module that obtains coordinate information of an external input that is applied from the outside of the electronic apparatus ED. The input sensing module of the electronic apparatus ED may be driven by various suitable methods, such as a capacitive method, a resistive method, an infrared method, and a pressure method, and embodiments are not limited to any one method.

In an embodiment, the input sensing module may be on the display module DM. The input sensing module may be directly on the display module DM by continuous processes, but embodiments are not limited thereto. The input sensing module may be manufactured separately from the display module DM and then attached to the display module DM by an adhesive layer. In an embodiment, the input sensing module may be located between components of the display module DM. For example, the input sensing module may be located between the display substrate DP and the light control substrate LCM.

In embodiments, the electronic apparatus ED may further include an electronic module, which includes various suitable functional modules for operating the display module DM, the power module PM (see FIG. 1) for supplying power required for the electronic apparatus ED or for generating power required for the operation of the electronic apparatus ED, and a bracket, which is coupled to the display module DM and/or the outer case HAU to divide the inner space of the electronic apparatus ED.

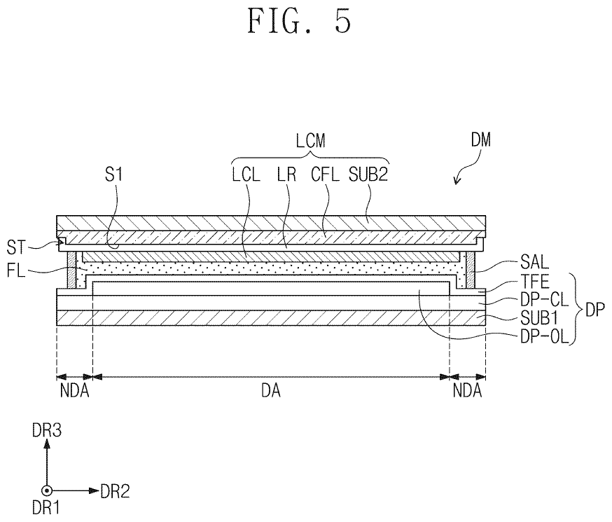

FIG. 5 is a cross-sectional view of a display module according to an embodiment. Referring to FIG. 5, the display module DM may include a display substrate DP (or a first substrate), a light control substrate LCM (or a second substrate), and a sealing member SAL and a filling member FL which are arranged between the display substrate DP and the light control substrate LCM. The descriptions given above may equally apply to the display substrate DP and the light control substrate LCM.

Referring to FIG. 5, the display substrate DP may include a lower substrate SUB1, a circuit layer DP-CL, a light-emitting element layer DP-OL, and an encapsulation layer TFE.

The lower substrate SUB1 may include a glass substrate, a polymer substrate, and/or an organic/inorganic composite material substrate. The lower substrate SUB1 may include an upper surface and a lower surface that are parallel (e.g., substantially parallel) to each of the first direction DR1 and the second direction DR2. The lower substrate SUB1 may include a display region DA and a non-display region NDA and may provide a base surface on which components of the display substrate DP are stacked. The circuit layer DP-CL, the light-emitting element layer DP-OL, and the encapsulation layer TFE may be sequentially stacked on the upper surface of the lower substrate SUB1 in the third direction DR3, and these layers may be defined as the first substrate.

The light-emitting element layer DP-OL may include light-emitting elements arranged in the display region DA. The circuit layer DP-CL may be located between the light-emitting element layer DP-OL and the lower substrate SUB1 and may include drive elements, signal lines, and pads connected to the light-emitting elements. In the display region DA, the light-emitting elements of the light-emitting element layer DP-OL may provide source light (or first light) toward the light control substrate LCM.

The encapsulation layer TFE may be on the light-emitting element layer DP-OL and seal the light-emitting elements. The encapsulation layer TFE may include a plurality of thin films. The thin films of the encapsulation layer TFE may be provided to improve the optical efficiency of the light-emitting elements and/or to protect the light-emitting elements.

The light control substrate LCM may include an upper substrate SUB2, a color filter layer CFL, a low-refractive layer LR, and a light conversion layer LCL.

The upper substrate SUB2 may include a glass substrate, a polymer substrate, and/or an organic/inorganic composite material substrate. The upper substrate SUB2 may include a front surface and a back surface that are parallel (e.g., substantially parallel) to each of the first direction DR1 and the second direction DR2. The back surface of the upper substrate SUB2 may face the upper surface of the lower substrate SUB1. The upper substrate SUB2 may provide a base surface on which components of the light control substrate LCM are stacked. The color filter layer CFL, the low-refractive layer LR, and the light conversion layer LCL may be sequentially stacked on the back surface of the upper substrate SUB2 in the third direction DR3, and these layers may be defined as the second substrate.

The light conversion layer LCL may overlap the display region DA and include light conversion portions that convert the optical characteristics of source light provided by the light-emitting elements. The light conversion layer LCL may selectively transmit the source light or selectively convert the wavelength of the source light. The light conversion layer LCL may partially overlap the non-display region NDA.

The color filter layer CFL may overlap the display region DA and filter rays of light that have passed through the light conversion layer LCL. The color filter layer CFL may absorb light that is not converted by the light conversion layer LCL, thereby preventing or reducing a deterioration in the color purity of the electronic apparatus ED (see FIG. 3). The color filter layer CFL may include color filters that display the same color as pixels. Accordingly, the color filter layer CFL may filter external light into the same colors as the pixels, and the reflectance of external light may be reduced.

The color filter layer CFL may partially overlap the non-display region NDA. The color filter layer CFL may include color filters arranged in the non-display region NDA so as to overlap each other, and may absorb light that is emitted or reflected via the non-display region NDA.

The low-refractive layer LR may be located between the light conversion layer LCL and the color filter layer CFL. The low-refractive layer LR may have a relatively lower refractive index than a light conversion portion of the light conversion layer LCL. The low-refractive layer LR may improve the light emission efficiency of the electronic apparatus ED through the light recycling using the refractive index. This is described in more detail below.

The sealing member SAL may be located between the display substrate DP and the light control substrate LCM and may couple the display substrate DP to the light control substrate LCM. The sealing member SAL may overlap the non-display region NDA. The display substrate DP and the light control substrate LCM may be formed individually through separate processes, and the display module DM may be manufactured by bonding the display substrate DP to the light control substrate LCM via the sealing member SAL. The sealing member SAL may include a UV-curable material. However, the material of the sealing member SAL is not limited to the example described above.

The filling member FL may be located between the display substrate DP and the light control substrate LCM and may fill an empty space, overlapping the display region DA, between the display substrate DP and the light control substrate LCM. In an embodiment, the filling member FL may be located between the encapsulation layer TFE of the display substrate DP and the light conversion layer LCL of the light control substrate LCM. The filling member FL may include silicon, epoxy, and/or acrylic-based thermosetting materials. However, the material of the sealing member FL is not limited to the example described above.

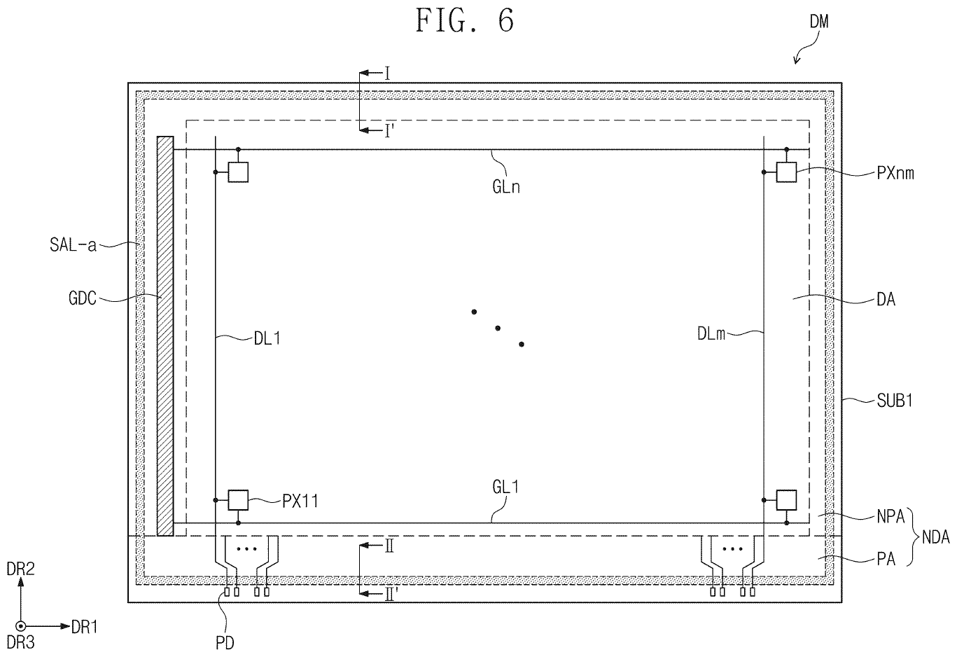

FIG. 6 is a plan view of a display module according to an embodiment of the present disclosure. FIG. 6 shows some components of the display module DM if (e.g., when) viewed in the third direction DR3. FIG. 6 schematically shows some components of the display substrate DP in the display module DM.

Referring to FIG. 6, the lower substrate SUB1 of the display module DM may include a display region DA and a non-display region NDA. The display module DM may include pixels PX11 to PXnm arranged in the display region DA and signal lines GL1 to GLn and DL1 to DLm electrically connected to the pixels PX11 to PXnm. The display module DM may include drive circuits GDC and pads PD arranged in the non-display region NDA.

Each of the pixels PX11 to PXnm may include a pixel drive circuit that includes a light-emitting element and a plurality of transistors (e.g., a switching transistor, a drive transistor, and/or the like) connected to the light-emitting element, which is described below. The pixels PX11 to PXnm may emit light in response to electrical signals applied to the pixels PX11 to PXnm. FIG. 6 shows an example in which the pixels PX11 to PXnm are arranged in a matrix form, but the arrangement of the pixels PX11 to PXnm is not limited thereto.

The signal lines GL1 to GLn and DL1 to DLm may include gate lines GL1 to GLn and data lines DL1 to DLm. Each of the pixels PX11 to PXnm may be connected to a corresponding gate line among the gate lines GL1 to GLn and a corresponding data line among the data lines DL1 to DLm. Depending on the configuration of pixel drive circuits of the pixels PX11 to PXnm, more various suitable types (or kinds) of signal lines may be provided in the display module DM.

The drive circuit GDC may include a gate drive circuit. The gate drive circuit may generate gate signals and sequentially output the gate signals to the gate lines GL1 to GLn. The gate drive circuit may output another control signal to the pixel drive circuits of pixels PX11 to PXnm.

The non-display region NDA may include a pad region PA in which the pads PD are arranged and a non-pad region NPA adjacent to the pad region PA. The non-display region NDA may be divided into the pad region PA and the non-pad region NPA. The pad region PA may extend in the first direction DR1, and the non-pad region NPA may extend from the pad region PA in the second direction DR2. The display region DA may be defined as a quadrilateral shape including four sides in a plan view. Also, the pad region PA may surround one selected from the four sides, and the non-pad region NPA may surround the remaining three sides. The pad region PA may surround one side parallel (e.g., substantially parallel) to the first direction DR1. Also, a portion of the non-pad region NPA may surround the other side parallel (e.g., substantially parallel) to the first direction DR1, and another portion of the non-pad region NPA may surround two sides parallel (e.g., substantially parallel) to the second direction DR2.

The pads PD may be arranged on the pad region PA in the first direction DR1. The pads PD may be parts connected to a circuit board. Each of the pads PD may be connected to a corresponding signal line among the plurality of signal lines GL1 to GLn and DL1 to DLm and connected to a corresponding pixel via the signal line. The pads PD may have a shape integrated with the signal lines GL1 to GLn and DL1 to DLm. However, embodiments are not limited thereto, and the pads PD may be arranged in a layer different from that of the signal lines GL1 to GLn and DL1 to DLm and connected thereto via contact holes.

FIG. 6 shows an example of a sealing member placement region SAL-a corresponding to a region in which the sealing member SAL (see FIG. 5) is located, in a plan view. The sealing member placement region SAL-a may overlap the non-display region NDA and may correspond to a portion of the non-display region NDA. The sealing member placement region SAL-a may be adjacent to the edge of the display module DM and extend in a direction in which the edge of the display module DM extends. The sealing member placement region SAL-a may surround the display region DA in a plan view. In an embodiment, the sealing member placement region SAL-a may be located outside the region in which the drive circuit GDC is placed.

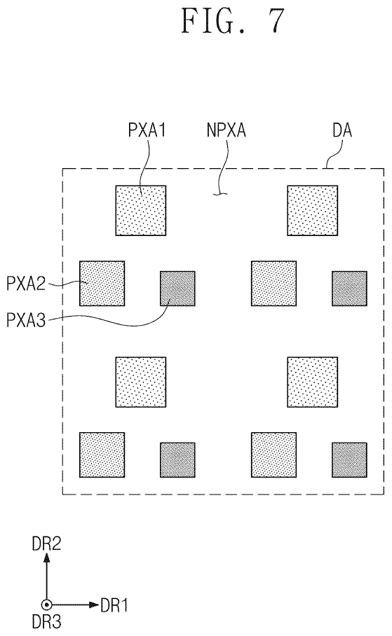

FIG. 7 is an enlarged plan view of a display substrate according to an embodiment of the present disclosure. FIG. 7 is an enlarged view of a portion of the display substrate DP corresponding to the display region DA (see FIG. 6) described above.

Referring to FIG. 7, the display region DA may include light-emitting regions PXA1, PXA2, and PXA3 corresponding to light-emitting elements and a non-light emitting region NPXA surrounding the light-emitting regions PXA1, PXA2, and PXA3. FIG. 7 illustrates an example of the arrangement and shapes of the light-emitting regions PXA1, PXA2, and PXA3.

The light-emitting regions PXA1, PXA2, and PXA3 may each correspond to a region from which light provided by the light-emitting elements is emitted. The light-emitting regions PXA1, PXA2, and PXA3 may include a first light-emitting region PXA1, a second light-emitting region PXA2, and a third light-emitting region PXA3. The first to third light-emitting regions PXA1, PXA2, and PXA3 may be distinguished from each other on the basis of the colors of light emitted to the outside of the electronic apparatus ED. The non-light emitting region NPXA may set boundaries between the first to third light-emitting regions PXA1, PXA2, and PXA3, and may prevent or reduce color mixing between the first to third light-emitting regions PXA1, PXA2, and PXA3.

One selected from the first to third light-emitting regions PXA1, PXA2, and PXA3 may provide first color light corresponding to source light provided by a light-emitting element, another may provide second color light different from the first color light, and the other may provide third color light different from the first color light and the second color light. For example, the first color light may be blue light, the second color light may be red light, and the third color light may be green light. However, the examples of color light are not necessarily limited thereto.

The first to third light-emitting regions PXA1, PXA2, and PXA3 may be arranged in a certain pattern and repeat inside the display region DA. Some of the first to third light-emitting regions PXA1, PXA2, and PXA3 may be arranged side by side in the first direction DR1 to form rows, and may be arranged side by side in the second direction DR2 to form columns.

The first to third light-emitting regions PXA1, PXA2, and PXA3 may have various suitable shapes in a plan view. For example, each of the first to third light-emitting regions PXA1, PXA2, and PXA3 may have a quadrangular shape as shown in FIG. 7. However, embodiments are not limited thereto, and each of the first to third light-emitting regions PXA1, PXA2, and PXA3 may have a polygonal, circular (e.g., generally circular), elliptical, or irregular shape.

The first to third light-emitting regions PXA1, PXA2, and PXA3 may have the same shape in a plan view. However, embodiments are not limited thereto, and at least some of the first to third light-emitting regions PXA1, PXA2, and PXA3 may have different shapes.

At least some of the first to third light-emitting regions PXA1, PXA2, and PXA3 may have different areas in a plan view. However, embodiments are not limited thereto, and the first to third light-emitting regions PXA1, PXA2, and PXA3 may have the same area.

The areas of the first to third light-emitting regions PXA1, PXA2, and PXA3 may be set according to the color of emitted light. For example, a light-emitting region for emitting green light, which is one of main colors, may have the largest area, and a light-emitting region for emitting blue light may have the smallest area. However, embodiments are not necessarily limited thereto and may suitably vary depending on the structure of the display substrate DP.

In an embodiment, the first to third light-emitting regions PXA1, PXA2, and PXA3 may have the same shape but different areas in a plan view. The first to third light-emitting regions PXA1, PXA2, and PXA3 may have quadrangular shapes having different planar areas. FIG. 7 shows that the first to third light-emitting regions PXA1, PXA2, and PXA3 have quadrangular shapes with right angles at the corners, but embodiments are not limited thereto. The first to third light-emitting regions PXA1, PXA2, and PXA3 may also have quadrangular shapes with substantially rounded corners.

The first to third light-emitting regions PXA1, PXA2, and PXA3 may each be provided in a plurality and arranged in a certain arrangement. The first light-emitting regions PXA1 arranged in the first direction DR1 may be defined as a first group, and the second light-emitting regions PXA2 and the third light-emitting regions PXA3 arranged in the first direction DR1 may be defined as a second group. In the second group, the second light-emitting regions PXA2 and the third light-emitting regions PXA3 may be arranged alternately in the first direction DR1.

The first group including the first light-emitting regions PXA1 may be provided in plurality arranged in the first direction DR1, and similarly, the second group including the second light-emitting regions PXA2 and the third light-emitting regions PXA3 may be provided in plurality arranged in the first direction DR1. As shown in FIG. 7, the first groups and the second groups may be arranged alternately in the second direction DR2.

Also, the arrangement form of the first to third light-emitting regions PXA1, PXA2, and PXA3 shown in FIG. 7 is only an example, and embodiments are not limited thereto. The arrangement form of the light-emitting regions may suitably vary depending on the design of the electronic apparatus ED. For example, the shape, area, and arrangement of the light-emitting regions may be designed in various suitable manners depending on the light emission efficiency of the colors, and are not limited to the embodiments shown in FIG. 7.

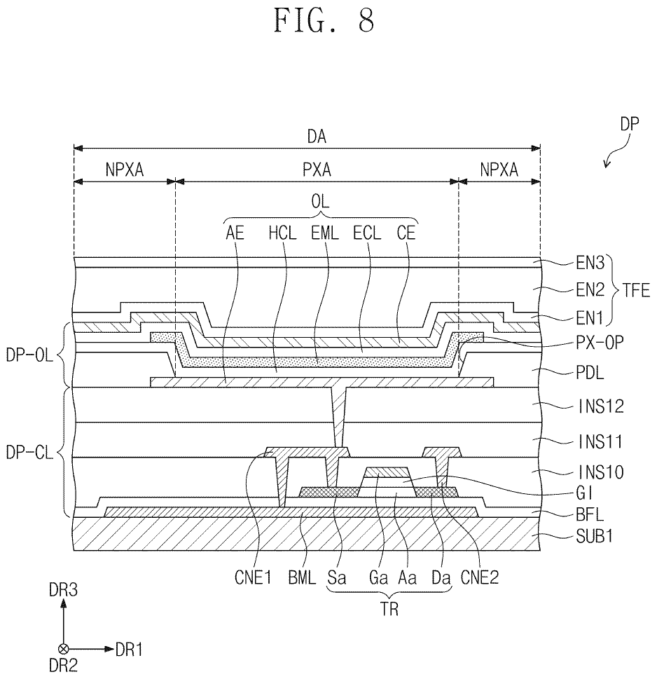

FIG. 8 is a cross-sectional view of a display substrate according to an embodiment of the present disclosure.

Each pixel of the display substrate DP may have an equivalent circuit including transistors, at least one capacitor, and a light-emitting element, and the equivalent circuit diagram of the pixel may be modified in various suitable forms. FIG. 8 corresponds to one light-emitting region PXA and shows an example of a transistor TR and a light-emitting element OL that are included in a pixel. The light-emitting region PXA shown in FIG. 8 may correspond to one selected from the first to third light-emitting regions PXA1, PXA2, and PXA3 shown in FIG. 7.

Referring to FIG. 8, the display substrate DP may include a lower substrate SUB1, a circuit layer DP-CL, a light-emitting element layer DP-OL, and an encapsulation layer TFE, and the description given above may equally apply to each of these components.

The display substrate DP may include an insulating layer (e.g., electrically insulating layer), a semiconductor pattern, a conductive layer (e.g., electrically conductive layer) and/or a conductive pattern (e.g., electrically conductive pattern), a signal line, and/or the like. During the manufacturing of the display substrate DP, the insulating layer, the semiconductor layer, and the conductive layer may be formed on the lower substrate SUB1 by a coating and/or deposition method, and then, the insulating layer, the semiconductor layer, and the conductive layer may be selectively patterned by a photolithography process. Through these processes, the semiconductor pattern, the conductive pattern, and the signal line of the display substrate DP may be formed.

The lower substrate SUB1 may provide a base surface on which the circuit layer DP-CL is formed. The lower substrate SUB1 may have a single-layer structure or a multi-layer structure. For example, the lower substrate SUB1 having the multi-layer structure may include synthetic resin layers and at least one inorganic layer arranged between the synthetic resin layers, or may include a glass substrate and a synthetic resin layer on the glass substrate. However, embodiments of the lower substrate SUB1 are not limited thereto.

The synthetic resin layer in the lower substrate SUB1 may include at least one selected from acryl-based resin, methacryl-based resin, polyisoprene, vinyl-based resin, epoxy-based resin, urethane-based resin, cellulose-based resin, siloxane-based resin, polyamide-based resin, perylene-based resin, or polyimide-based resin. However, the material of the synthetic resin layer is not limited to the examples described above.

The circuit layer DP-CL may be on the lower substrate SUB1. The circuit layer DP-CL may include at least one insulating layer (e.g., electrically insulating layer), a conductive pattern (e.g., electrically conductive pattern), and a semiconductor pattern. Also, a stack structure of the circuit layer DP-CL may suitably vary depending on the manufacturing process of the circuit layer DP-CL and the configuration of the elements included in the pixels. FIG. 8 shows an example of a stack shape of the circuit layer DP-CL. However, this is only an example, and the circuit layer DP-CL according to the present disclosure is not limited to any one embodiment if (e.g., when) a circuit layer includes drive elements for driving pixels.

The circuit layer DP-CL may include a light-blocking pattern BML, a transistor TR, connection electrodes CNE1 and CNE2, an insulating pattern GI (e.g., electrically insulating pattern GI), a buffer layer BFL, and a plurality of insulating layers INS10, INS11, and INS12 (e.g., electrically insulating layer INS10, INS11, and INS12).

The light-blocking pattern BML may be on the lower substrate SUB1. The light-blocking pattern BML may prevent conductive patterns (e.g., electrically conductive patterns) of the circuit layer DP-CL from being visible due to external light (or reduce visibility thereof). The light-blocking pattern BML may overlap the transistor TR. The light-blocking pattern BML may prevent or reduce damage to the semiconductor pattern of the transistor TR by external light.

The buffer layer BFL may be on the lower substrate SUB1 so as to cover the light-blocking pattern BML. In the buffer layer BFL, a contact hole may be defined to expose a portion of the light-blocking pattern BML. The buffer layer BFL may improve the coupling strength between the lower substrate SUB1 and the semiconductor pattern of the transistor TR.

The buffer layer BFL may include inorganic materials. For example, the buffer layer BFL may include at least one selected from aluminum oxide, titanium oxide, silicon oxide, silicon nitride, silicon oxynitride, zirconium oxide, or hafnium oxide. However, the material of the buffer layer BFL is not limited to the examples described above.

The transistor TR may be on the buffer layer BFL. The transistor TR may include a semiconductor pattern. The semiconductor pattern of the transistor TR may be arranged in a certain rule across pixels according to the equivalent circuit. The semiconductor pattern may include polysilicon. However, embodiments are not limited thereto, and the semiconductor pattern may include amorphous silicon, crystalline oxide, and/or non-crystalline oxide.

A source region Sa, a drain region Da, and a channel region Aa of the transistor TR may be formed from the semiconductor pattern. The semiconductor pattern may be divided into a plurality of regions according to conductivity. For example, the electrical characteristics of a semiconductor pattern may suitably vary depending on whether the semiconductor pattern is doped or whether metal oxide is reduced. A region that is highly conductive (e.g., highly electrically conductive) in the semiconductor pattern may serve as an electrode or a signal line, and this region may correspond to the source region Sa and drain region Da of the transistor TR. A region that is not doped or not reduced and thus has relatively low conductivity (e.g., relatively low electrical conductivity) may correspond to the channel region Aa (or the active region) of the transistor TR.

The insulating pattern GI may be on the semiconductor pattern of the transistor TR. The insulating pattern GI may be formed by forming an insulating layer (e.g., electrically insulating layer) on the semiconductor pattern of the transistor TR and then patterning the insulating layer. The gate electrode Ga of the transistor TR may be on the insulating pattern GI. The gate electrode Ga may be used as a mask during the process of forming the insulating pattern GI. The gate electrode Ga may overlap the channel region Aa and may be spaced apart from the semiconductor pattern of the transistor TR with the insulating pattern GI therebetween in a cross-section.

The plurality of insulating layers INS10, INS11, and INS12 may be on the buffer layer BFL. Each of the plurality of insulating layers INS10, INS11, and INS12 may include at least one inorganic film and/or organic film. For example, the inorganic films of the insulating layers INS10, INS11, and INS12 may include at least one selected from aluminum oxide, titanium oxide, silicon oxide, silicon nitride, silicon oxynitride, zirconium oxide, or hafnium oxide. The organic films of the insulating layers INS10, INS11, and INS12 may include phenolic polymer, acrylic polymer, imide polymer, aryl ether polymer, amide polymer, fluorine polymer, p-xylene polymer, vinyl alcohol polymer, and a polymer combination thereof. However, the insulating layers INS10, INS11, and INS12 are not limited to the materials described above.

The first insulating layer INS10 may be on the buffer layer BFL. The first insulating layer INS10 may cover the gate electrode Ga. The connection electrodes CNE1 and CNE2 may be on the first insulating layer INS10.

The connection electrodes CNE1 and CNE2 may include a first connection electrode CNE1 and a second connection electrode CNE2. The first connection electrode CNE1 may be connected to the source region Sa of the transistor TR via a contact hole that passes through the first insulating layer INS10. The first connection electrode CNE1 may be connected to the light-blocking pattern BML via a contact hole that passes through the first insulating layer INS10 and the buffer layer BFL. The second connection electrode CNE2 may be connected to the drain region Da of the transistor TR via a contact hole that passes through the first insulating layer INS10. The second connection electrode CNE2 may extend in a plan view and may be connected to another transistor or wire.

The second insulating layer INS11 and the third insulating layer INS12 may be on the first insulating layer INS10 so as to cover the connection electrodes CNE1 and CNE2. The first connection electrode CNE1 may be connected to a first electrode AE of the light-emitting element OL, which is on the third insulating layer INS12, via a contact hole that passes through the second insulating layer INS11 and the third insulating layer INS12.

In an embodiment, the third insulating layer INS12 may include an organic film. The third insulating layer INS12 may provide a flat upper surface for components that are on the third insulating layer INS12. However, embodiments are not necessarily limited thereto.

The light-emitting element layer DP-OL may be on the circuit layer DP-CL. The light-emitting element layer DP-OL may include a light-emitting element OL and a pixel-defining layer PDL. Although FIG. 8 shows one light-emitting element OL as an example, the light-emitting element layer DP-OL may include a plurality of light-emitting elements OL.

In the display region DA, the light-emitting element layer DP-OL may include the light-emitting region PXA corresponding to the light-emitting element OL and the non-light emitting region NPXA surrounding the light-emitting region PXA. The light-emitting element OL may include a first electrode AE, a hole control layer HCL, a light-emitting layer EML, an electron control layer ECL, and a second electrode CE.

The pixel-defining layer PDL may be on the third insulating layer INS12. In the pixel-defining layer PDL, a light-emitting opening PX-OP may be defined to expose a portion of the first electrode AE. The pixel-defining layer PDL may partially cover the upper surface of the first electrode AE. In embodiments, a portion of the first electrode AE exposed through the light-emitting opening PX-OP may correspond to the light-emitting region PXA. A region in which the pixel-defining layer PDL is located may correspond to the non-light emitting region NPXA surrounding the light-emitting region PXA.

The pixel-defining layer PDL may include polymer resin. For example, the pixel-defining layer PDL may include polyacrylate resin and/or polyimide resin. The pixel-defining layer PDL may be made of an inorganic material in addition to the polymer resin. In embodiments, the pixel-defining layer PDL may include the inorganic material. For example, the pixel-defining layer PDL may include silicon nitride (SiNₓ), silicon oxide (SiOₓ), silicon oxynitride (SiOₓN_{y}), and/or the like.

Also, in an embodiment, the pixel-defining layer PDL may include a light-absorbing material. The pixel-defining layer PDL may include a black coloring agent. The black coloring agent may include black dye and black pigment. The black coloring agent may include carbon black, metal such as chromium, and/or oxide thereof. However, embodiments of the pixel-defining layer PDL are not limited to the examples described above.

The hole control layer HCL may be on the first electrode AE and the pixel-defining layer PDL. The hole control layer HCL may be shared by the pixels. The hole control layer HCL may overlap the light-emitting region PXA and the non-light emitting region NPXA. The hole control layer HCL may include at least one selected from a hole transport layer or a hole injection layer.

The light-emitting layer EML may be on the hole control layer HCL. The light-emitting layer EML may be located in a region that corresponds to the light-emitting opening PX-OP of the pixel-defining layer PDL. The light-emitting layer EML may include an organic light-emitting material, an inorganic light-emitting material, a quantum dot, and/or a quantum rod. The light-emitting layer EML may have a light-emitting pattern form that is provided separately for each of the pixels. However, embodiments are not limited thereto, and the light-emitting layer EML may be formed as a common layer shared by the pixels. The light-emitting layer EML may generate the first light, which is the source light. For example, the first light may be blue light, but embodiments are not necessarily limited thereto.

Also, in an embodiment, the light-emitting element OL may have a tandem structure that includes a plurality of light-emitting layers on the first electrode AE in the third direction DR3. The light-emitting layers may generate substantially the same color light. However, embodiments are not limited thereto. Some of the light-emitting layers may generate substantially the same color light, and the other light-emitting layers may generate different color light. For example, the light-emitting element OL according to an embodiment may include four light-emitting layers. In this case, three of the four light-emitting layers may generate blue light, and one light-emitting layer may generate green light. However, embodiments of the light-emitting layer EML of the tandem structure are not necessarily limited thereto. The light-emitting element having a tandem structure may further include functional layers, such as a hole control layer, an electron control layer, and a charge generation layer, which are arranged between the light-emitting layers.

The electron control layer ECL may be on the light-emitting layer EML. The electron control layer ECL may be shared by the pixels. The electron control layer ECL may overlap the light-emitting region PXA and the non-light emitting region NPXA. The electron control layer ECL may include at least one selected from an electron transport layer or an electron injection layer.

The second electrode CE may be on the electron control layer ECL. The second electrode CE may be shared by the pixels. The second electrode CE may overlap the light-emitting region PXA and the non-light emitting region NPXA. A common voltage may be supplied to the pixels via the second electrode CE. Accordingly, the second electrode CE may be referred to as a common electrode.

A first voltage may be applied to the first electrode AE via the transistor TR, and a common voltage may be applied to the second electrode CE. A hole and an electron injected into the light-emitting layer EML are coupled to each other to form an exciton, and if (e.g., when) the exciton transitions to the ground state, the light-emitting element OL may emit light.

The encapsulation layer TFE may be on the light-emitting element layer DP-OL and seal the light-emitting element OL. The encapsulation layer TFE may include first to third encapsulation layers EN1, EN2, and EN3. The first encapsulation layer EN1 may be on the second electrode CE, and the second encapsulation layer EN2 and the third encapsulation layer EN3 may be sequentially on the first encapsulation layer EN1.

In an embodiment, the first and third encapsulation layers EN1 and EN3 may each include an inorganic film, and the inorganic film may protect the light-emitting element layer DP-OL from moisture and/or oxygen. For example, the inorganic film may include, but is not limited to, at least one selected from aluminum oxide, titanium oxide, silicon oxide, silicon nitride, silicon oxynitride, zirconium oxide, or hafnium oxide.

In an embodiment, the second encapsulation layer EN2 may include an organic film, and the organic film may protect the light-emitting element layer DP-OL from foreign substances, such as dust particles. For example, the organic film may include acrylic resin, but embodiments are not limited to the examples described above.

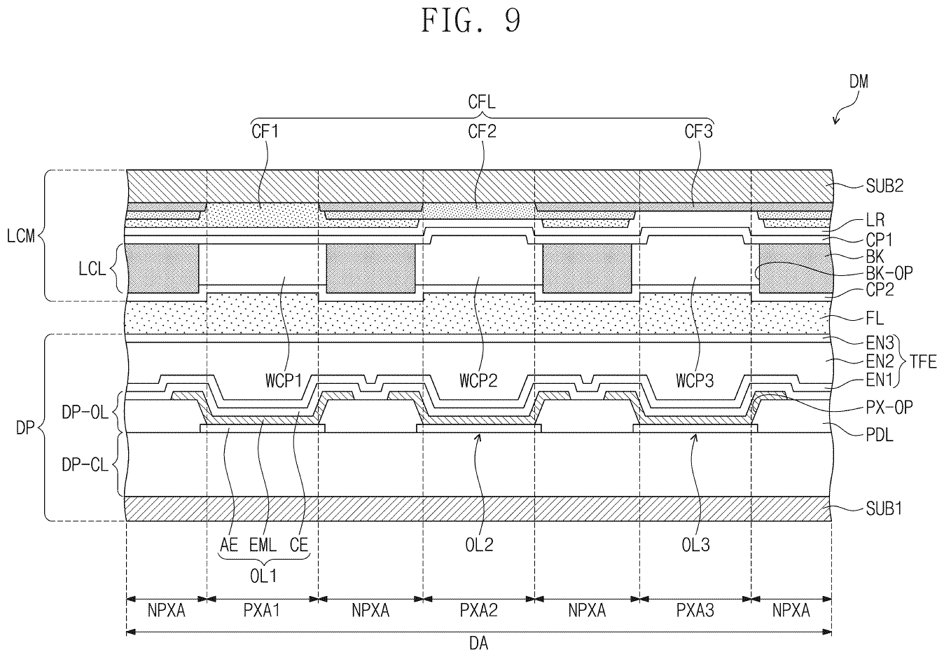

FIG. 9 is a cross-sectional view of a display module according to an embodiment of the present disclosure. FIG. 9 shows an example of a partial cross-sectional view of the display module DM corresponding to the first to third light-emitting regions PXA1, PXA2, and PXA3 arranged in the display region DA. The description given above may equally apply to each component of the display module DM shown in FIG. 9.

Referring to FIG. 9, the light-emitting element layer DP-OL may include a plurality of light-emitting elements OL1, OL2, and OL3. Each of the plurality of light-emitting elements OL1, OL2, and OL3 may include the first electrode AE, the light-emitting layer EML, and the second electrode CE described above. Although omitted in FIG. 9, each of the light-emitting elements OL1, OL2, and OL3 may further include the hole control layer HCL (see FIG. 8) and the electron control layer ECL (see FIG. 8) described above.

The first electrodes AE of the light-emitting elements OL1, OL2, and OL3 may be spaced apart from each other on the circuit layer DP-CL. In the pixel-defining layer PDL, a plurality of light-emitting openings PX-OP may be defined to respectively expose portions of the first electrodes AE. The first electrodes AE of the first to third light-emitting elements OL1, OL2, and OL3 exposed by the light-emitting openings PX-OP may correspond to the first to third light-emitting regions PXA1, PXA2, and PXA3, respectively.

The light-emitting layers EML of the light-emitting elements OL1, OL2, and OL3 may respectively correspond to the light-emitting openings PX-OP. However, embodiments are not limited thereto, and the light-emitting layers EML of the light-emitting elements OL1, OL2, and OL3 may have a single integrated shape.

The second electrodes CE of the light-emitting elements OL1, OL2, and OL3 may be connected to each other and provided as a single body. The second electrode CE provided as a single body may overlap the first to third light-emitting regions PXA1, PXA2, and PXA3 and the non-light emitting region NPXA.

The light control substrate LCM may include the upper substrate SUB2, the color filter layer CFL, the low-refractive layer LR, and the light conversion layer LCL, which are above the display substrate DP. In an embodiment, the light control substrate LCM may further include a first capping layer CP1 located between the low-refractive layer LR and the light conversion layer LCL and a second capping layer CP2 located on the back surface of the light conversion layer LCL.

The back surface of the upper substrate SUB2 may face the upper surface of the lower substrate SUB1. Referring to FIG. 9, the color filter layer CFL, the low-refractive layer LR, the first capping layer CP1, the light conversion layer LCL, and the second capping layer CP2 may be sequentially on the back surface of the upper substrate SUB2 in the third direction DR3.

The color filter layer CFL may include a first color filter CF1, a second color filter CF2, and a third color filter CF3. The first to third color filters CF1, CF2, and CF3 may be provided on the back surface of the upper substrate SUB2 and patterned so as to overlap corresponding regions among the first to third light-emitting regions PXA1, PXA2, and PXA3. During the manufacturing process of the light control substrate LCM, the third color filter CF3, the second color filter CF2, and the first color filter CF1 may be sequentially formed on the back surface of the upper substrate SUB.

The first to third color filters CF1, CF2, and CF3 may correspond to the first to third light-emitting regions PXA1, PXA2, and PXA3, respectively, in a plan view. For example, the first color filter CF1 may overlap the first light-emitting region PXA1, the second color filter CF2 may overlap the second light-emitting region PXA2, and the third color filter CF3 may overlap the third light-emitting region PXA3. The first to third color filters CF1, CF2, and CF3 are described in more detail below.

The low-refractive layer LR may be located between the light conversion layer LCL and the color filter layer CFL. In the manufacturing process of the light control substrate LCM, the low-refractive layer LR may cover the back surface (or the lower surface), facing the display substrate DP, of the color filter layer CFL formed on the upper substrate SUB2.

The low-refractive layer LR may have a lower refractive index than each of a first light conversion portion WCP1, a second light conversion portion WCP2, and a transmissive portion WCP3 of the light conversion layer LCL, which is described below. For example, the refractive index of the low-refractive layer LR may be about 1.1 to about 1.5, or, for example, about 1.1 to about 1.35. However, the refractive index of the low-refractive layer LR is not limited to the numerical examples described above. The low-refractive layer LR may include a low-refractive organic film having a relatively low refractive index. The low-refractive layer LR may further include scattering particles (e.g., light scattering particles) which are dispersed in the organic film.

The low-refractive layer LR above the light conversion layer LCL may cause light, which has not been converted by the light conversion portions WCP1 and WCP2, to be incident onto the light conversion portions WCP1 and WCP2 again by utilizing the refractive index. The light that is re-incident into the light conversion portions WCP1 and WCP2 by the low-refractive layer LR may be converted by the light conversion portions WCP1 and WCP2. For example, the low-refractive layer LR may improve the light emission efficiency of the electronic apparatus ED (see FIG. 3) through the recycling of light by utilizing the refractive index.

The low-refractive layer LR may include a material having high light transmittance. For example, the low-refractive layer LR may have high transmittance of about 90% or more. Because the low-refractive layer LR has high light transmittance, the light that passes through the light conversion layer LCL and is emitted toward the front surface of the display module DM may travel without obstruction.

The first capping layer CP1 may be on the back surface, facing the display substrate DP, of the low-refractive layer LR. The first capping layer CP1 may include an inorganic material. In the manufacturing process of the light control substrate LCM, the first capping layer CP1 may be on the low-refractive layer LR and cover the low-refractive layer LR. The first capping layer CP1 may prevent or reduce penetration of moisture and/or gas into the low-refractive layer LR. Also, in the manufacturing process of the light control substrate LCM, the first capping layer CP1 may be provided as a base surface for forming the light conversion layer LCL and may protect the light conversion layer LCL.

The second capping layer CP2 may be on the back surface (or the lower surface) of the light conversion layer LCL and cover the light conversion layer LCL. In an embodiment, the second capping layer CP2 may include an inorganic material. The second capping layer CP2 may prevent or reduce penetration of moisture and/or foreign materials into the light conversion layer LCL. The second capping layer CP2 may prevent or reduce deterioration of the light conversion layer LCL due to moisture.

Also, the stacking order of the components of the light control substrate LCM is not limited to that shown in FIG. 9. For example, the light control substrate LCM may include a plurality of low-refractive layers, one of the plurality of low-refractive layers may be located between the color filter layer CFL and the light conversion layer LCL, and another may be located on the back surface of the light conversion layer LCL.

The light conversion layer LCL may include a first light conversion portion WCP1, a second light conversion portion WCP2, a transmissive portion WCP3, and a bank portion BK. Although FIG. 9 shows examples of cross-sectional views of one first light conversion portion WCP1, one second light conversion portion WCP2, and one transmissive portion WCP3, the first and second light conversion portions WCP1 and WCP2 and the transmissive portion WCP3 may each be provided in plurality in the display region DA.

The bank portion BK may overlap the non-light emitting region NPXA in a plan view. In the bank portion BK, a plurality of openings BK-OP may be defined so as to correspond to the first to third light-emitting regions PXA1, PXA2, and PXA3. The first light conversion portion WCP1, the second light conversion portion WCP2, and the transmissive portion WCP3 may respectively correspond to the plurality of openings BK-OP of the bank portion BK. If (e.g., when) the first and second light conversion portions WCP1 and WCP2 and the transmissive portion WCP3 are provided in plurality, the bank portion BK may surround the plurality of first light conversion portions WCP1, the plurality of second light conversion portions WCP2, and the plurality of transmissive portions WCP3.

The bank portion BK may prevent or reduce color mixing by setting boundaries between the first light conversion portion WCP1, the second light conversion portion WCP2, and the transmissive portion WCP3. The bank portion BK may include a material having certain color. For example, the bank portion BK may include black dye and/or black pigment.

The first light conversion portion WCP1, the second light conversion portion WCP2, and the transmissive portion WCP3 may correspond to the first to third light-emitting regions PXA1, PXA2, and PXA3, respectively, in a plan view. For example, the first light conversion portion WCP1 may overlap the first light-emitting region PXA1, the second light conversion portion WCP2 may overlap the second light-emitting region PXA2, and the transmissive portion WCP3 may overlap the third light-emitting region PXA3.

The light-emitting elements OL1, OL2, and OL3 may each provide the source light (or the first light). In an embodiment, the source light may be blue light. However, embodiments are not limited thereto, and the source light may correspond to light that is provided by a stack of light-emitting layers for emitting blue light and at least one light-emitting layer for emitting green light.

The first light conversion portion WCP1 and the second light conversion portion WCP2 may each include base resin and quantum dots dispersed in the base resin. The quantum dots may convert the wavelength ranges of the source light provided by the light-emitting elements OL1, OL2, and OL3. For example, the first light conversion portion WCP1 may include first quantum dots that convert first light, provided by the first light-emitting element OL1, into second light having a wavelength range different from the wavelength range of the first light. The second light conversion portion WCP2 may include second quantum dots that convert first light, provided by the second light-emitting element OL2, into third light having a wavelength range different from the wavelength range of the first light. In this case, the wavelength range of the second light may differ from the wavelength range of the third light.

In an embodiment, the first quantum dots of the first light conversion portion WCP1 may convert the source light, provided by the first light-emitting element OL1, into green light. The second quantum dots of the second light conversion portion WCP2 may convert the source light, provided by the second light-emitting element OL2, into red light. The quantum dots in the light conversion portions WCP1 and WCP2 are described in more detail below.

The transmissive portion WCP3 may include base resin. The transmissive portion WCP3 may allow the source light, provided from the third light-emitting element OL3, to pass therethrough. For example, the third light-emitting element OL3 may provide blue light, and the blue light may pass through the transmissive portion WCP3 and be emitted toward the front surface of the display module DM.

Accordingly, the display module DM may emit green light via the first light-emitting region PXA1, emit red light via the second light-emitting region PXA2, and emit blue light via the third light-emitting region PXA3. The display module DM may display a certain image on the display region DA via the first to third light-emitting regions PXA1, PXA2, and PXA3, which display green, red, and blue, respectively. However, the color of light emitted through these regions is not necessarily limited thereto.

The transmissive portion WCP3 may further include scattering particles (e.g., light scattering particles) dispersed in the base resin. The scattering particles in the transmissive portion WCP3 may scatter, in various suitable directions, light incident toward the transmissive portion WCP3. Embodiments are not limited thereto, and the first and second light conversion portions WCP1 and WCP2 may also include scattering particles (e.g., light scattering particles) dispersed in the base resin.

The scattering particles may scatter, in various suitable directions, light that passes through the light conversion portion or the transmissive portion. Scattering particles (e.g., light scattering particles) may be particles that have relatively large density and/or specific gravity. The scattering particles may include titanium oxide (TiO₂), silica-based nanoparticles, and/or the like. As the light conversion portion includes the scattering particles, the light conversion efficiency by the quantum dots in the light conversion portion may be improved.

The first to third color filters CF1, CF2, and CF3 may each include base resin and pigment and/or dye dispersed in the base resin. Each of the first to third color filters CF1, CF2, and CF3 may allow light having a set or specific wavelength range to pass therethrough and absorb most of the light having a wavelength range other than the set or specific wavelength range. For example, one selected from the first to third color filters CF1, CF2, and CF3 may include a red color filter, another may include a green color filter, and the other may include a blue color filter.

The red color filter may allow the red light to pass therethrough and absorb most of the green light and the blue light. The green color filter may allow the green light to pass therethrough and absorb most of the red light and the blue light. The blue color filter may allow the blue light to pass therethrough and absorb most of the red light and the green light. However, the colors of color filters are not limited to the descriptions above.

The first color filter CF1 may be above the first light conversion portion WCP1. The first color filter may allow the second light, provided from the first light conversion portion WCP1, to pass therethrough. For example, the first light conversion portion WCP1 may convert the blue light, provided from the first light-emitting element OL1, into the green light, and the first color filter CF1 may allow the green light, provided from the first light conversion portion WCP1, to pass therethrough. The first color filter CF1 may absorb the red light and the blue light incident toward the first color filter CF1. Therefore, the first light that is not changed by the first light conversion portion WCP1 and is incident toward the first color filter CF1 may be absorbed therein, and thus, degradation of color purity in the first light-emitting region PXA1 may be prevented or reduced.

The second color filter CF2 may be above the second light conversion portion WCP2 and may allow the third light, provided from the second light conversion portion WCP2, to pass therethrough. For example, the second light conversion portion WCP2 may convert the blue light, provided from the second light-emitting element OL2, into the red light, and the second color filter CF2 may allow the red light, provided from the second light conversion portion WCP2, to pass therethrough. The second color filter CF2 may absorb the green light and the blue light incident toward the second color filter CF2. Therefore, the first light that is not changed by the second light conversion portion WCP2 and is incident toward the second color filter CF2 may be absorbed therein, and thus, degradation of color purity in the second light-emitting region PXA2 may be prevented or reduced.

The third color filter CF3 may be above the transmissive portion WCP3 and may allow the first light passing through the transmissive portion WCP3 to pass therethrough. For example, the transmissive portion WCP3 may allow the blue light, provided from the third light-emitting element OL3, to pass therethrough, and the blue light passing through the transmissive portion WCP3 may be transmitted through the third color filter CF3.

External light, such as natural light, may be incident from the outside of the display module DM toward the display substrate DP. The external light may include red light, green light, and blue light. If (e.g., when) the display module DM does not include the color filter layer CFL, the external light incident toward the display substrate DP may be reflected by the conductive patterns (e.g., signal lines, electrodes, and/or the like) inside the display substrate DP and then provided to a user, and the user may perceive the reflected light.

The first to third color filters CF1, CF2, and CF3 may prevent or reduce the reflection of external light. The first color filter CF1, which allows the second light to pass therethrough, may absorb light that corresponds to the wavelength ranges of the first light and the third light among the light provided from outside. For example, the first color filter CF1 may be a green color filter, which absorbs light corresponding to the red light and the blue light among the external light, thereby filtering the light into the green light. By the similar principle, the second color filter CF2 may be a red color filter, which absorbs light corresponding to the green light and the blue light among the external light, thereby filtering the light into the red light. The third color filter CF3 may be a blue color filter, which absorbs light corresponding to the red light and the green light among the external light, thereby filtering the light into the blue light.

In an embodiment, the first to third color filters CF1, CF2, and CF3 may overlap each other in the non-light emitting region NPXA. In embodiments, the first to third color filters CF1, CF2, and CF3 may overlap each other in the third direction DR3 above a region in which the bank portion BK is provided. The first to third color filters CF1, CF2, and CF3, which overlap each other, may block light that passes through the non-light emitting region NPXA and may thus prevent or reduce color mixing between the first to third light-emitting regions PXA1, PXA2, and PXA3.

Also, the color filter layer CFL may further include a partition wall that is located in the non-light emitting region NPXA. The partition wall may surround the first to third color filters CF1, CF2, and CF3 that overlap the light-emitting regions PXA1, PXA2, and PXA3, respectively, and may set boundaries between the first to third color filters CF1, CF2, and CF3. The partition wall of the color filter layer CFL may include a material having a certain color, and for example, the partition wall may include black pigment and/or black dye. The partition wall of the color filter layer CFL may absorb light and prevent or reduce color mixing.

The cores of the quantum dots in the first light conversion portion WCP1 and the second light conversion portion WCP2 may be selected from a group II-VI compound, a group III-VI compound, a group I-III-VI compound, a group III-V compound, a group IV-VI compound, a group IV element, a group IV compound, and a combination thereof.

The group II-VI compound may be selected from the group consisting of: a binary compound selected from the group consisting of CdSe, CdTe, CdS, ZnS, ZnSe, ZnTe, ZnO, HgS, HgSe, HgTe, MgSe, MgS, and a mixture thereof; a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof; and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof. Also, the group II-VI semiconductor compound may further include a group I metal and/or a group IV element. The group III-VI compound may be selected from CuSnS or CuZnS, and the group II-IV-VI compound may be selected from ZnSnS, and/or the like. The group I-II-IV-VI compound may be selected from a quaternary compound selected from the group consisting of Cu₂ZnSnS₂, Cu₂ZnSnS₄, Cu₂ZnSnSe₄, Ag₂ZnSnS₂, and a mixture thereof.

The group III-VI compound may include binary compounds, such as In₂S₃ and/or In₂Se₃, ternary compounds, such as InGaS₃ and/or InGaSe₃, or any combination thereof.

The group I-III-VI compound may be selected from ternary compounds selected from the group consisting of AgInS, AgInS₂, CuInS, CuInS₂, AgGaS₂, CuGaS₂, CuGaO₂, AgGaO₂, AgAlO₂, and a mixture thereof, and/or quaternary compounds, such as AgInGaS₂ and/or CuInGaS₂.

The group III-V compound may be selected from the group consisting of: a binary compound selected from the group consisting of GaN, GaP, GaAs, GaSb, AlN, AlP, AlAs, AlSb, InN, InP, InAs, InSb, and a mixture thereof; a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and a mixture thereof; and a quaternary compound selected from the group consisting of GaAlNP, GaAlNAs, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof. Also, the group III-V compound may further include group II metal. For example, InZnP and/or the like may be selected as the group III-II-V compound.

The group IV-VI compound may be selected from the group consisting of: a binary compound selected from the group consisting of SnS, SnSe, SnTe, PbS, PbSe, PbTe, and a mixture thereof; a ternary compound selected from the group consisting of SnSeS, SnSeTe, SnSTe, PbSeS, PbSeTe, PbSTe, SnPbS, SnPbSe, SnPbTe, and a mixture thereof; and a quaternary compound selected from the group consisting of SnPbSSe, SnPbSeTe, SnPbSTe, and a mixture thereof.

Examples of the group II-IV-V semiconductor compound may include a ternary compound selected from the group consisting of ZnSnP, ZnSnP₂, ZnSnAs₂, ZnGeP₂, ZnGeAs₂, CdSnP₂, CdGeP₂, and a mixture thereof.

The group IV element may be selected from the group consisting of Si, Ge, and a mixture thereof. The group IV compound may be a binary compound selected from the group consisting of SiC, SiGe, and a mixture thereof.

Each element contained in multi-element compounds, such as the binary compound, the ternary compound, and the quaternary compound, may exist in a particle at a uniform concentration or at non-uniform concentrations. For example, the chemical formula indicating the quantum dot represents the type (or kind) of elements contained in the quantum dot compound, and the atomic ratio in the compound may suitably vary. For example, AgInGaS₂ may represent AgInₓGa₁₋ₓS₂ (where x is a real number between 0 and 1).

Also, the binary compound, the ternary compound, and/or the quaternary compound may exist in the particle at a uniform (e.g., substantially uniform) concentration, or may be divided into states in which the concentration distributions thereof are partially different from each other and exist in the same particle. In embodiments, a core/shell structure in which one quantum dot surrounds another quantum dot is also possible. The core/shell structure may have a concentration gradient in which the concentration of elements present in the shell decreases toward the core.

In some embodiments, the quantum dot may have a core-shell structure that includes a core having nanocrystals and a shell surrounding the core as described above. The shell of quantum dots may act as a protective layer for preventing or reducing chemical degradation of the core and maintaining semiconductor properties and/or as a charging layer for imparting electrophoretic properties to quantum dots. The shell may have a single layer or a plurality of layers. Examples of the shell of the quantum dot may include metal and/or non-metal oxide, a semiconductor compound, or a combination thereof.

For example, the examples of the metal and/or non-metal oxide may include binary compounds, such as SiO₂, Al₂O₃, TiO₂, ZnO, MnO, Mn₂O₃, Mn₃O₄, CuO, FeO, Fe₂O₃, Fe₃O₄, CoO, Co₃O₄, and/or NiO, and/or ternary compounds, such as MgAl₂O₄, CoFe₂O₄, NiFe₂O₄, and/or CoMn₂O₄, but embodiments of the present disclosure are not limited thereto.

Also, the examples of the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, and AlSb, but embodiments of the present disclosure are not limited thereto.

The quantum dot may have a full width of half maximum (FWHM) of an emission wavelength spectrum of about 45 nm or less, about 40 nm or less, or, for example, about 30 nm or less, and in this range, color purity and color reproducibility may be improved. In embodiments, the light emitted from these quantum dots is emitted in all (e.g., substantially all) directions, which improves the optical viewing angle.

Also, the shape of quantum dot is not specifically limited to those generally used in the art. However, for example, nanoparticles, nanotubes, nanowires, nanofibers, nanoplate particles, and/or the like, in the form of spherical, pyramidal, multi-arm, or cubic shapes may be used.

In the quantum dots, the energy band gap may be controlled by adjusting the size of the quantum dots and/or the ratio of elements in the quantum dot compound. Accordingly, light of various suitable wavelengths may be obtained from a quantum dot light-emitting layer. Therefore, the light-emitting element that emits light having multiple wavelengths may be obtained by using quantum dots as described above (using quantum dots of different sizes and/or quantum dots with different ratios of elements in the quantum dot compound). For example, the size of the quantum dots and the ratio of the elements in the quantum dot compound may be selected to emit red, green, and/or blue light. In embodiments, the quantum dots may be configured to emit white light due to the combination of light of various suitable colors.

The particle size of quantum dots decreases, the light in a short wavelength region may be emitted. For example, in quantum dots having the same core, the particle size of quantum dots that emit green light may be smaller than the particle size of quantum dots that emit red light. Also, in quantum dots having the same core, the particle size of quantum dots that emit blue light may be smaller than the particle size of quantum dots that emit green light. However, embodiments are not limited thereto, and even in quantum dots having the same core, the particle size may be adjusted according to a material for forming a shell and a thickness of the shell. Also, if (e.g., when) the light-emitting layer EML described above includes quantum dot materials, the description of quantum dots given above may equally apply to the quantum dot materials included in the light-emitting layer EML.

The first substrate provided as the display substrate DP may be formed by sequentially stacking, on the upper surface of the lower substrate SUB1, the circuit layer DP-CL, the light-emitting element layer DP-OL, and the encapsulation layer TFE in the third direction DR3. The second substrate provided as the light control substrate LCM may be formed by sequentially stacking, on the back surface of the upper substrate SUB2, the color filter layer CFL, the low-refractive layer LR, the first capping layer CP1, the light conversion layer LCL, and the second capping layer CP2 in the third direction DR3.

The first substrate and the second substrate, which have been manufactured, are provided such that the upper surface of the first substrate faces the back surface of the second substrate, and the filling member FL may be applied between the first substrate and the second substrate. For example, the filling member FL may be located between the encapsulation layer TFE of the first substrate and the light conversion layer LCL of the second substrate. The display substrate DP and the light control substrate LCM may be bonded to each other with the filling member FL therebetween, and a space, between the first substrate and the second substrate, overlapping the display region DA, may be filled with the filling member FL.

In embodiments, the display module DM according to an embodiment may further include a column spacer located between the display substrate DP and the light control substrate LCM. The column spacer may be provided in plurality, and the column spacers may be spaced apart from each other and arranged corresponding to the non-light emitting region NPXA so as not to degrade the light emission efficiency of the display substrate DP. The column spacers may overlap the bank portion BK in a plan view. The column spacers may support the display substrate DP and the light control substrate LCM so that the display substrate DP and the light control substrate LCM are bonded to each other in a flat state during the process of bonding the display substrate DP to the light control substrate LCM.

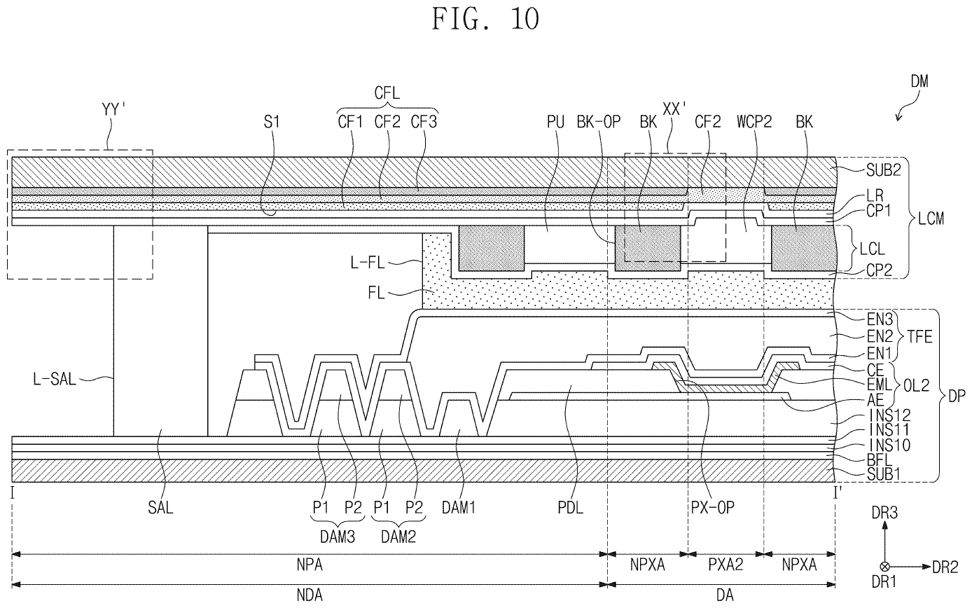

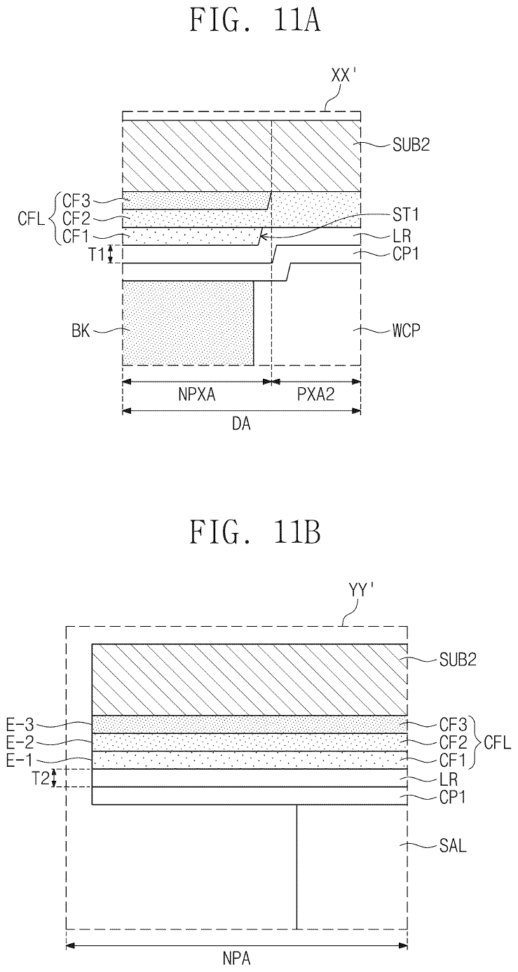

FIG. 10 is a cross-sectional view of a display module according to an embodiment of the present disclosure. FIGS. 11A and 11B are enlarged cross-sectional views of a display module according to an embodiment of the present disclosure. FIG. 10 is a cross-sectional view taken along line I-I′ of FIG. 6. FIG. 11A is an enlarged cross-sectional view of a display module corresponding to a region XX′ of FIG. 10. FIG. 11B is an enlarged cross-sectional view of a display module corresponding to a region YY′ of FIG. 10.

FIG. 10 is an example of a cross-sectional view of the display module DM that corresponds to the non-pad region NPA and the display region DA adjacent to the non-pad region NPA. FIG. 10 shows an example of the second light-emitting element OL2 and the second light conversion portion WCP2 corresponding to the second light-emitting region PXA2 located adjacent to the non-pad region NPA, but components located adjacent to the non-display region NDA are not limited thereto. The description given above may equally apply to each of the components shown in FIG. 10, and thus, the following description is focused on components not described above.

Referring to FIG. 10, the buffer layer BFL, the first insulating layer INS10, and the second insulating layer INS11 on the upper surface of the lower substrate SUB1 may extend from the display region DA toward the non-display region NDA.

The display substrate DP may include a plurality of dams DAM1, DAM2, and DAM3 arranged in the non-display region NDA. The dams DAM1, DAM2, and DAM3 may be above the lower substrate SUB1. In an embodiment, the dams DAM1, DAM2, and DAM3 may be on the second insulating layer INS11.

The dams DAM1, DAM2, and DAM3 may include a first dam DAM1, a second dam DAM2, and a third dam DAM3, which are spaced apart from each other and arranged in a direction from the display region DA toward the non-display region NDA. The first dam DAM1 among the dams DAM1, DAM2, and DAM3 may be located closest to the display region DA, and the third dam DAM3 among the dams DAM1, DAM2, and DAM3 may be located farthest from the display region DA. Also, the number of dams DAM1, DAM2, and DAM3 is not limited to the embodiments described above, and may be more or less than that shown in the diagram.

At least some of the dams DAM1, DAM2, and DAM3 may have different heights in the third direction DR3. For example, the height of the first dam DAM1 may be less than the height of each of the second dam DAM2 and the third dam DAM3. However, embodiments are not limited thereto, and the dams DAM1, DAM2, and DAM3 may all have the same height.

At least some of the dams DAM1, DAM2, and DAM3 may have different stacking structures. For example, the first dam DAM1 may include the same material as the third insulating layer INS12. The second dam DAM2 and the third dam DAM3 may each include a first layer P1 and a second layer P2 that are sequentially stacked in the third direction DR3. The first layer P1 may include the same material as the third insulating layer INS12, and the second layer P2 may include the same material as the pixel-defining layer PDL. The first layers P1 of the first dam DAM1 and the second dam DAM2 and the first layer P1 of the third dam DAM3 may be formed concurrently (e.g., simultaneously) during formation of the third insulating layer INS12, and the second layer P2 of the second dam DAM2 and the second layer P2 of the third dam DAM3 may be formed concurrently (e.g., simultaneously) during formation of the pixel-defining layer PDL. However, embodiments are not limited thereto, and the dams DAM1, DAM2, and DAM3 may all have the same structure with the same material.

The first encapsulation layer EN1 of the encapsulation layer TFE may extend from the display region DA toward the non-display region NDA and may be on dams DAM1, DAM2, and DAM3. The first encapsulation layer EN1 of the encapsulation layer TFE may be in contact with the dams DAM1, DAM2, and DAM3.

The second encapsulation layer EN2 of the encapsulation layer TFE may be on the first encapsulation layer EN1. The formation region of the second encapsulation layer EN2 including the organic film may be defined by the dams DAM1, DAM2, and DAM3. In the manufacturing process of the display substrate DP, the second encapsulation layer EN2, which has flowability, may flow toward the non-display region NDA and be blocked by one selected from the dams DAM1, DAM2, and DAM3. FIG. 10 shows an example in which the flow of the second encapsulation layer EN2 is blocked in a space between the first dam DAM1 and the second dam DAM2.

The third encapsulation layer EN3 may be on the second encapsulation layer EN2 so as to cover the second encapsulation layer EN2. The third encapsulation layer EN3 may extend toward the non-display region NDA further outward than the second encapsulation layer EN2. Referring to FIG. 10, the third encapsulation layer EN3 may be on the second dam DAM2 that blocks the flow of the second encapsulation layer EN2 and on the third dam DAM3 that is located further outward than the second dam DAM2. The third encapsulation layer EN3 may be in contact with the first encapsulation layer EN1 on the second dam DAM2 and the third dam DAM3, and may seal the second encapsulation layer EN2 together with the first encapsulation layer EN1. Accordingly, penetration of moisture and oxygen into the second encapsulation layer EN2 from the outside may be prevented or reduced.

The sealing member SAL may be provided in the non-display region NDA. The sealing member SAL may be on the second insulating layer INS11. However, embodiments are not necessarily limited thereto, and the arrangement thereof may suitably vary depending on the arrangement of the insulating layer of the display substrate DP. For example, the sealing member SAL may be on the first insulating layer INS10 or may be in contact with the lower substrate SUB1. Also, in embodiments, some of the conductive patterns of the circuit layer DP-CL may be arranged between the insulating layers in the non-display region NDA, and according to embodiments, some of the conductive patterns may overlap the sealing member SAL in a plan view.

The dams DAM1, DAM2, and DAM3 may be spaced apart from the sealing member SAL in a plan view. The dams DAM1, DAM2, and DAM3 may prevent or reduce extension of the encapsulation layer TFE to an outer region of the non-display region NDA in which the sealing member SAL is placed.

The filling member FL may be located between the display substrate DP and the light control substrate LCM. In the process of bonding the light control substrate LCM to the display substrate DP, the filling member FL may fill an empty space, corresponding to the display region DA, between the display substrate DP and the light control substrate LCM. The filling member FL may be formed by curing flowable resin. However, embodiments are not limited thereto. The filling member FL may be omitted, and a gap may be left between the display substrate DP and the light control substrate LCM.

The filling member FL may be spaced apart from the sealing member SAL in a plan view. For example, one side surface L-FL of the filling member FL may be spaced apart from the sealing member SAL. However, embodiments are not limited thereto, and in some regions, the filling member FL may be in contact with the sealing member SAL.

The light conversion layer LCL may further include a dummy pattern PU. The bank portion BK may be located in the display region DA, and a portion thereof may be located in the non-display region NDA. For example, some of the openings BK-OP of the bank portion BK may overlap the non-display region NDA, and the dummy pattern PU may be located in the opening BK-OP of the bank portion BK which overlaps the non-display region NDA. The dummy pattern PU may be spaced apart from the light-emitting element provided in the display region DA in a plan view. The dummy pattern PU does not overlap the light-emitting elements, and thus, no light may be emitted via the dummy pattern PU.

The dummy pattern PU may include base resin and quantum dots. In an embodiment, the light conversion portions WCP1 and WCP2 (see FIG. 9) described above may be formed by an inkjet method. In order to prevent or reduce uneven distribution of quantum dots in the light conversion portions WCP1 and WCP2 (see FIG. 9) formed at an early stage of the process, a composition may be preliminarily applied to a region not overlapping the light-emitting elements, before forming the light conversion portions WCP1 and WCP2 (see FIG. 9) in the display region DA. The dummy pattern PU may correspond to a region that is preliminarily formed before the light conversion portions WCP1 and WCP2 (see FIG. 9) that overlap the light-emitting elements are formed. Also, in an embodiment, the dummy pattern PU may be omitted.

The color filter layer CFL may extend from the display region DA toward the non-display region NDA. The color filter layer CFL may include first to third color filters CF1, CF2, and CF3.

The first to third color filters CF1, CF2, and CF3 may have different colors. For example, the first to third color filters CF1, CF2, and CF3 may each include one selected from a green color filter, a red color filter, and a blue color filter. In the display module DM, the first to third color filters CF1, CF2, and CF3 overlapping each other in the thickness direction may prevent or reduce emission and/or entrance of light via the non-display region NDA. Also, the first to third color filters CF1, CF2, and CF3 overlapping each other in the third direction DR3 may prevent or reduce reflection of external light that is incident toward the non-display region NDA.

Referring to FIGS. 10 and 11A, the color filter layer CFL located in the non-light emitting region NPXA may include first to third color filters CF1, CF2, and CF3 that overlap each other in the third direction DR3. Each of the first to third color filters CF1, CF2, and CF3 may include a back surface facing the display substrate DP. The second color filter CF2 may be on the back surface of the third color filter CF3, and the first color filter CF1 may be on the back surface of the second color filter CF2.

Also, the stacking order of the first to third color filters CF1, CF2, and CF3 is not limited to that shown in the diagram, and may suitably vary depending on the order in which the first to third color filters CF1, CF2, and CF3 are formed during the manufacturing process of the light control substrate LCM.

The color filter layer CFL may include a first surface S1 that faces the display substrate DP. The first surface S1 of the color filter layer CFL may be the back surface (or the lower surface) of the color filter layer CFL. The first surface S1 of the color filter layer CFL may face the display substrate DP and correspond to the back surfaces of the first to third color filters CF1, CF2, and CF3 that are in contact with the low-refractive layer LR.

The first surface S1 of the color filter layer CFL may include a first stepped region ST1 that overlaps the non-light emitting region NPXA. The first stepped region ST1 may be provided by a difference in heights between the back surfaces of the first to third color filters CF1, CF2, and CF3, which form the first surface S1 of the color filter layer CFL. The first stepped region ST1 may be provided by placing the edge of one selected from the color filters CF1, CF2, and CF3, which overlap the non-light emitting region NPXA, on the back surface of another one selected from the color filters CF1, CF2, and CF3. For example, the first stepped region ST1 may be formed by placing the edge of the first color filter CF1 on the back surface of the second color filter CF2. However, an embodiment according to the present disclosure is not limited to the structure described above, and the edges of the first to third color filters CF1, CF2, and CF3 overlapping the non-light emitting region NPXA may be at least partially misaligned with each other. For example, unlike that shown in the diagram, the first stepped region ST1 may include a (1-1)-th stepped region, which is formed by placing the edge of the first color filter CF1 on the back surface of the second color filter CF2, and a (1-2)-th stepped region, which is formed by placing the edge of the second color filter CF2 on the back surface of the third color filter CF3.

The low-refractive layer LR may extend from the display region DA toward the non-display region NDA. The low-refractive layer LR may be on the first surface S1 of the color filter layer CFL. A first thickness T1 of the low-refractive layer LR overlapping the display region DA is about 0.3 μm to about 1.0 μm.

The low-refractive layer LR may be derived from a resin composition. The low-refractive layer LR may be formed by applying a resin composition onto the first surface S1 of the color filter layer CFL and curing the applied resin composition.

The viscosity of the resin composition is about 1.5 cP to about 2.5 cP. For example, the viscosity of the resin composition may be about 2.0 cP to about 2.5 cP. Accordingly, the low-refractive layer LR overlapping the display region DA may have a small thickness of about 0.3 μm to about 1.0 μm.

The resin composition may contain a solvent, and the solvent may include a first solvent and a second solvent. The solvent may be made of the first solvent and the second solvent. The viscosity of each of the first solvent and the second solvent may be about 1.0 cP to about 2.5 cP. For example, the viscosity of each of the first solvent and the second solvent may be about 1.0 cP to about 1.5 cP. The first solvent may contain propylene glycol monomethyl ether acetate (PGMEA), and the second solvent may contain γ-butyrolactone (GBL). The weight percentage of the first solvent relative to the total weight of the solvent may be about 75% to about 90%, and the weight percentage of the second solvent relative to the total weight of the solvent may be about 10% to about 25%.

The weight percentage of solids relative to the total weight of the resin composition may be about 6% to about 10%. For example, the weight percentage of solids relative to the total weight of the resin composition may be about 8% to about 10%.

The low-refractive layer LR may be on the first stepped region ST1 that overlaps the non-light emitting region NPXA. The low-refractive layer LR may be in contact with the back surfaces and edges of the first to third color filters CF1, CF2, and CF3 that form the first stepped region ST1. For example, the low-refractive layer LR may be in contact with the edge of the first color filter CF1 and the back surface of the second color filter CF2. Because the first thickness T1 of the low-refractive layer LR is in a range of about 0.3 μm to about 1.0 μm, at least a portion of the low-refractive layer LR on the first stepped region ST1 may be discontinuous. For example, if (e.g., when) the resin composition is applied, a gap may occur between the low-refractive layer LR and the edge of the first color filter CF1 due to the first stepped region ST1, and at least a portion of the low-refractive layer LR may be disconnected due to the gap. Also, the resin composition may not be applied to at least a portion of the edge of the first color filter CF1 due to the first stepped region ST1, and thus, at least a portion of the low-refractive layer LR may be spaced apart from the edge of the first color filter CF1.

The low-refractive layer LR has a small thickness and/or is discontinuous in the display region DA, for example, in the non-light emitting region NPXA adjacent to the non-pad region NPA, and thus, a path for gas and/or moisture to enter from the outside via the low-refractive layer LR may be blocked or reduced. Accordingly, deterioration of the components of the light control substrate LCM due to gas and/or moisture entering from outside may be prevented or reduced. Therefore, it is possible to prevent or reduce visibility of stains in the display region DA due to the deterioration thereof, and the reliability of the display module DM may be improved.

Referring to FIGS. 10 and 11B, the color filter layer CFL located in the non-pad region NPA may include first to third color filters CF1, CF2, and CF3 that overlap each other in the third direction DR3. In the non-pad region NPA, the first surface S1 of the color filter layer CFL may not include a stepped region. The first surface S1 of the color filter layer CFL overlapping the non-pad region NPA may be substantially parallel to a surface defined by the first direction DR1 and the second direction DR2. Edges E-1, E-2, and E-3 of the first to third color filters CF1, CF2, and CF3 overlapping the non-pad region NPA may be aligned with each other.

The low-refractive layer LR may be on the first surface S1 of the color filter layer CFL that overlaps the non-pad region NPA. The back surface of the low-refractive layer LR overlapping the non-pad region NPA may be substantially parallel to the first surface S1 of the color filter layer CFL. A second thickness T2 of the low-refractive layer LR overlapping the non-pad region NPA may be about 0.3 μm to about 1.0 μm.

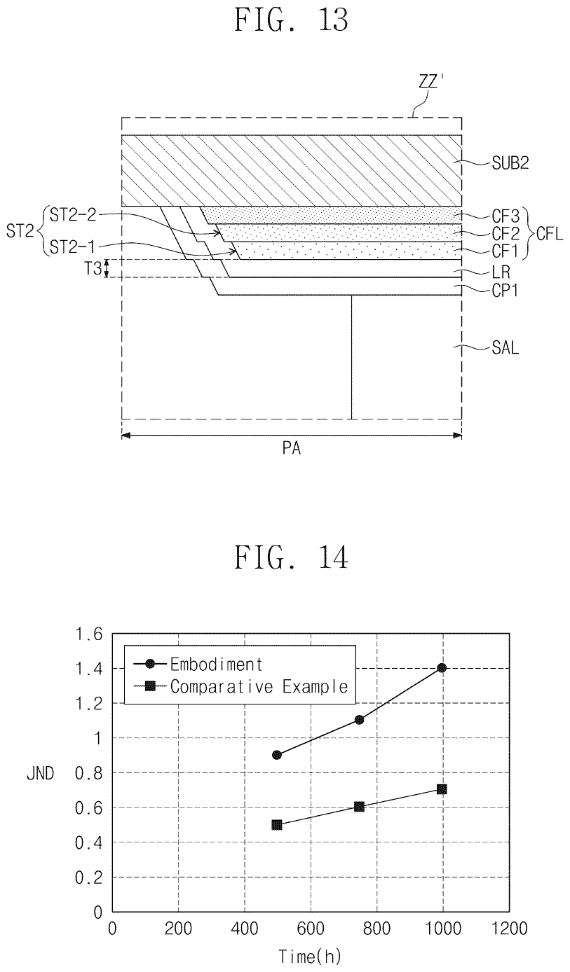

As described below, the edges of the first to third color filters CF1, CF2, and CF3 overlapping the pad region PA (see FIG. 13) may not be aligned with each other, but the edges of the first to third color filters CF1, CF2, and CF3 overlapping the non-pad region NPA may be aligned with each other. Accordingly, the low-refractive layer LR overlapping the non-pad region NPA is not on a stepped region, and thus, in the display region DA adjacent to the non-pad region NPA, a path for gas and/or moisture to enter via the low-refractive layer LR may not be blocked. In the display module DM according to an embodiment of the present disclosure, even if (e.g., when) there is no stepped region of the color filter layer CFL in a portion of the non-display region NDA, the low-refractive layer LR having the first thickness may be formed in the display region DA by using a low-viscosity resin composition, thereby improving reliability.

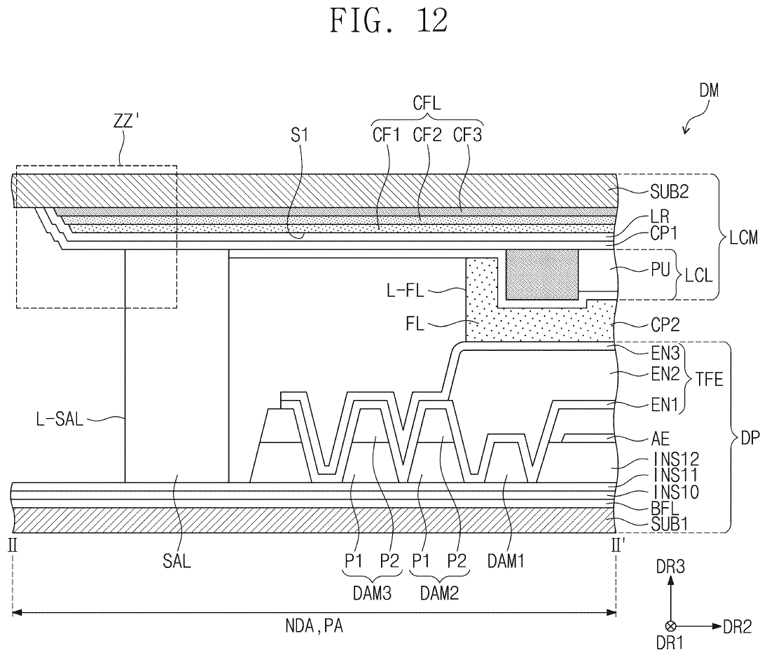

FIG. 12 is a cross-sectional view of a display module according to an embodiment of the present disclosure. FIG. 13 is an enlarged cross-sectional view of a display module according to an embodiment of the present disclosure. FIG. 12 is a cross-sectional view taken along line II-II′ of FIG. 6. FIG. 12 shows an example of a cross-sectional view of the display module DM overlapping the pad region PA. FIG. 13 is an enlarged cross-sectional view of a display module corresponding to a region ZZ′ of FIG. 12. The description given above may equally apply to each of the components shown in FIGS. 12 and 13, and thus, the following description is focused on components not described above.

Referring to FIGS. 12 and 13, the color filter layer CFL overlapping the pad region PA may include first to third color filters CF1, CF2, and CF3 that overlap each other in the third direction DR3.

The edges of the first to third color filters CF1, CF2, and CF3 in the pad region PA may be at least partially misaligned with each other. For example, the second color filter CF2 may extend toward the outside of the upper substrate SUB2 further than the first color filter CF1. The edge of the second color filter CF2 may protrude further than the edge of the first color filter CF1 in the direction from the center of the upper substrate SUB2 toward the outside. The third color filter CF3 may extend toward the outside of the upper substrate SUB2 further than the second color filter CF2. The edge of the third color filter CF3 may protrude further than the edge of the second color filter CF2 in the direction from the center of the upper substrate SUB2 toward the outside.

The first surface S1 of the color filter layer CFL may include a second stepped region ST2 that overlaps the pad region PA. The second stepped region ST2 may be provided by a difference in heights between the back surfaces of the first to third color filters CF1, CF2, and CF3, which form the first surface S1 of the color filter layer CFL. The second stepped region ST2 may include a (2-1)-th stepped region ST2-1 and a (2-2)-th stepped region ST2-2. The (2-1)-th stepped region ST2-1 may be formed by placing the edge of the first color filter CF1 on the back surface of the second color filter CF2, and the (2-2)-th stepped region ST2-2 may be formed by placing the edge of the second color filter CF2 on the back surface of the third color filter CF3. However, embodiments are not limited to the structure described above.

The low-refractive layer LR may be on the first surface S1 that overlaps the pad region PA. The low-refractive layer LR may be on the second stepped region ST2 that overlaps the pad region PA. The low-refractive layer LR may be in contact with the back surfaces and edges of the first to third color filters CF1, CF2, and CF3 that form the first stepped region ST1. For example, the low-refractive layer LR may be in contact with the edge of the first color filter CF1 and the back surface of the second color filter CF2.

A third thickness T3 of the low-refractive layer LR overlapping the pad region PA may be about 0.3 μm to about 2.0 μm. For example, the third thickness T3 of the low-refractive layer LR overlapping the pad region PA may be about 1.0 μm to about 1.5 μm.

Referring to FIG. 13 together with FIGS. 11A and 11B described above, the third thickness T3 of the low-refractive layer LR overlapping the pad region PA may be relatively greater than the second thickness T2 (see FIG. 11B) of the low-refractive layer LR overlapping the non-pad region NPA (see FIG. 11B). The third thickness T3 of the low-refractive layer LR overlapping the pad region PA may be relatively greater than the first thickness T1 (see FIG. 11A) of the low-refractive layer LR overlapping the display region DA (see FIG. 11A). The second stepped region ST2 may have a relatively large size of the stepped region, e.g., a relatively large distance between the edges of the first to third color filters CF1, CF2, and CF3, compared to the first stepped region ST1. Also, accordingly, even if (e.g., when) the third thickness T3 of the low-refractive layer LR is relatively greater than the first thickness T1 or the second thickness T2 of the low-refractive layer LR, the low-refractive layer LR on the second stepped region ST2 may be discontinuous.

Hereinafter, referring to an embodiment and a comparative example, the results of evaluating the characteristics of a display module according to an embodiment of the present disclosure are described. Also, the following embodiment is an example for assisting in understanding the present disclosure, and the scope of the present disclosure is not limited thereto.

### Manufacture of Display Module

Each of the embodiments and the comparative examples is manufactured by using the stacking structures of the display modules DM shown in FIG. 9 and FIG. 10.

A low-refractive layer LR in the embodiments is manufactured by applying a first resin composition and curing the same. The first resin composition has a viscosity of about 2.3 Cp and a solid content of about 9.5 wt %. The first resin composition includes a solvent that is made of a first solvent containing propylene glycol monomethyl ether acetate (PGMEA) and a second solvent containing γ-butyrolactone (GBL). A first solvent content in the total solvent is about 85 wt %, and a second solvent content in the total solvent is about 15 wt %.

A low-refractive layer LR in the comparative example is manufactured by applying a second resin composition and curing the same. The second resin composition has a viscosity of about 2.9 Cp and a solid content of about 12 wt %. The second solvent composition includes a solvent that is made of a first solvent containing propylene glycol monomethyl ether acetate (PGMEA), a second solvent containing γ-butyrolactone (GBL), and a third solvent containing methyl isobutyl carbinol (MIBC). A first solvent content in the total solvent is about 56 wt %, a second solvent content in the total solvent is about 28 wt %, and a third solvent content in the total solvent is about 16 wt %.

By the manufacturing steps described above, the first thickness T1 (see FIG. 11A) of the low-refractive layer LR in the embodiment is about 0.7 μm, and the first thickness T1 (see FIG. 11A) of the low-refractive layer LR in the comparative example is about 1.25 μm. Accordingly, the embodiment and the comparative example are manufactured to have different thicknesses.

### Evaluation of Display Module

FIG. 14 is a graph showing evaluation of the characteristics of the display modules in the embodiment and the comparative example. FIG. 14 shows just noticeable difference (JND) values over time for each of the embodiment and the comparative example. The JND refers to a quantitative index that evaluates the minimum difference threshold between two stimuli that may be detected by a user of an electronic apparatus, and the JND is measured to evaluate the degree of resolution for stain recognition issues in the display region.

Referring to FIG. 14, it can be seen that, compared to the comparison example, the embodiment has a relatively high JND value, thereby improving the visibility for the user of the electronic apparatus. The display module according to embodiments of the present disclosure includes the low-refractive layer having a thickness of about 1.0 μm or less in the display region. Accordingly, it is understood that the display module has the effect of preventing or reducing occurrence of defects in which stains are visible.

The display module according to embodiments of the present disclosure includes the low-refractive layer having a thickness of about 1.0 μm or less, and thus, the display module may have a small thickness or be discontinuous at the stepped region in the display region. Accordingly, it is possible to block or reduce an inflow path through which the gas and/or moisture flows into the low-refractive layer from the outside of the display module.

The electronic apparatus according to embodiments of the present disclosure may include the low-refractive layer in which the path for gas and/or moisture to enter is blocked or reduced. Accordingly, the electronic apparatus has the effect of improving light emission efficiency by using the low-refractive layer, and at the same time, it is possible to prevent or reduce occurrence of defects, such as peeling of the substrates of the display device and appearance of stains in the region adjacent to edges, thereby improving the reliability.

In the display module according to embodiments of the present disclosure and the electronic apparatus including the same, the low-refractive layer may be provided, in which the path for gas and/or moisture to enter is blocked or reduced. The light emission efficiency may be improved by the low-refractive layer, and at the same time, the defect in which stains are visible in the display region may be prevented or an occurrence thereof may be reduced. Accordingly, the reliability may be improved.

In the above, description has been made with reference to embodiments of the present disclosure, but those skilled or of ordinary skill in the art may understand that various suitable modifications and changes may be made to the present disclosure insofar as such modifications and changes do not depart from the spirit and technical scope of the present disclosure set forth in the claims to be described later.

Therefore, the technical scope of the present disclosure is not to be limited to the contents stated in the detailed description of the specification, but should be determined by the appended claims, and equivalents thereof.

What is claimed is:

1. A display module comprising:
a display substrate divided into a display region and a non-display region adjacent to the display region, the display substrate comprising light-emitting elements arranged in the display region; and
a light control substrate facing the display substrate and comprising a color filter layer, a light conversion layer, and a low-refractive layer located between the color filter layer and the light conversion layer,
wherein a first thickness of the low-refractive layer overlapping the display region is about 0.3 μm to about 1.0 μm.

2. The display module of claim 1, wherein the display region comprises a light-emitting region and a non-light emitting region surrounding the light-emitting region,
the color filter layer comprises a first color filter, a second color filter, and a third color filter having different colors, and
the first to third color filters overlapping the non-light emitting region overlap each other.

3. The display module of claim 2, wherein the color filter layer comprises a first surface facing the display substrate, and
the first surface comprises a first stepped region overlapping the non-light emitting region.

4. The display module of claim 3, wherein an edge of one selected from the first to third color filters overlapping the non-light emitting region is on a back surface of another one selected from the first to third color filters, thereby forming the first stepped region.

5. The display module of claim 1, wherein the non-display region comprises a pad region and a non-pad region adjacent to the pad region, and
the display substrate further comprises a plurality of pads arranged in the pad region.

6. The display module of claim 5, wherein a second thickness of the low-refractive layer overlapping the non-pad region is less than a third thickness of the low-refractive layer overlapping the pad region.

7. The display module of claim 5, wherein the color filter layer comprises a first color filter, a second color filter, and a third color filter having different colors, and
the first to third color filters overlapping the non-display region overlap each other.

8. The display module of claim 7, wherein edges of the first to third color filters overlapping the non-pad region are aligned with each other.

9. The display module of claim 7, wherein the color filter layer comprises a first surface facing the display substrate, and
the first surface comprises a second stepped region overlapping the pad region.

10. The display module of claim 7, wherein the second stepped region comprises a (2-1)-th stepped region and a (2-2)-th stepped region,
an edge of the first color filter overlapping the pad region is on a back surface of the second color filter overlapping the pad region, thereby providing the (2-1)-th stepped region, and
an edge of the second color filter overlapping the pad region is on a back surface of the third color filter overlapping the pad region, thereby providing the (2-2)-th stepped region.

11. The display module of claim 7, wherein the light conversion layer comprises:
a bank portion in which openings respectively overlapping the light-emitting elements are defined; and
a light conversion portion and a light transmissive portion respectively arranged in the openings,
wherein the light conversion portion comprises a quantum dot configured to convert a wavelength of source light of the light-emitting element.

12. The display module of claim 11, wherein a refractive index of the low-refractive layer is less than a refractive index of the light conversion portion.

13. The display module of claim 11, wherein the light conversion portion comprises:
a first light conversion portion configured to convert the source light into first color light; and
a second light conversion portion configured to convert the source light into second color light,
wherein the first color filter overlaps the first light conversion portion, the second color filter overlaps the second light conversion portion, and the third color filter overlaps the light transmissive portion.

14. The display module of claim 1, wherein the low-refractive layer is derived from a resin composition, and
viscosity of the resin composition is about 1.5 cP to about 2.5 cP.

15. The display module of claim 14, wherein a weight percentage of solids relative to a total weight of the resin composition is about 6% to about 10%.

16. The display module of claim 14, wherein the resin composition comprises a solvent comprising a first solvent and a second solvent,
the first solvent comprises propylene glycol monomethyl ether acetate (PGMEA), the second solvent comprises γ-butyrolactone (GBL), and
a weight percentage of the first solvent relative to a total weight of the solvent is about 75% to about 90%, and a weight percentage of the second solvent relative to the total weight of the solvent is about 10% to about 25%.

17. The display module of claim 1, wherein the light control substrate further comprises a capping layer covering a back surface of the low-refractive layer.

18. The display module of claim 1, further comprising a sealing member provided between the display substrate and the light control substrate and overlapping the non-display region.

19. A display module comprising:
a display substrate comprising light-emitting elements; and
a light control substrate facing the display substrate and comprising a color filter layer, a light conversion layer, and a low-refractive layer located between the color filter layer and the light conversion layer,
wherein the low-refractive layer is derived from a resin composition having viscosity of about 1.5 cP to about 2.5 cP, and
a thickness of the low-refractive layer is about 0.3 μm to about 1.0 μm.

20. An electronic apparatus for providing an image, the electronic apparatus comprising a display device and a power module configured to supply power to the display device,
wherein the display device comprises a display module and a window on the display module, and
the display module comprises:
a display substrate divided into a display region and a non-display region adjacent to the display region, the display substrate comprising light-emitting elements arranged in the display region; and
a light control substrate facing the display substrate and comprising a color filter layer, a light conversion layer, and a low-refractive layer located between the color filter layer and the light conversion layer,
wherein a first thickness of the low-refractive layer overlapping the display region is about 0.3 μm to about 1.0 μm.
